(19) United States
(12) Patent Application Publication
(10) Pub. No.: US 2016/0208096 A1
(43) Pub. Date: Jul. 21, 2016

(54) SOLUTION OF AROMATIC POLYAMIDE FOR PRODUCING DISPLAY ELEMENT, OPTICAL ELEMENT, ILLUMINATION ELEMENT OR SENSOR ELEMENT

(71) Applicants: AKRON POLYMER SYSTEMS, INC., Akron, OH (US); SUMITOMO BAKELITE COMPANY LIMITED, Shinagawa-ku (JP)

(72) Inventors: Limin Sun, Copley, OH (US); Dong Zhang, Uniontown, OH (US); Jiaokai Jing, Uniontown, OH (US); Frank W. Harris, Boca Raton, FL (US); Takehiko Maetani, Kawasaki-shi (JP); Ritsuya Kawasaki, Kobe-shi (JP); Toshihiko Katayama, Nishinomiya-shi (JP); Hideo Umeda, Kobe-shi (JP)

(73) Assignees: AKRON POLYMER SYSTEMS, INC., Akron, OH (US); SUMITOMO BAKELITE COMPANY LIMITED, Shinagawa-ku (JP)

(21) Appl. No.: 14/996,997

(22) Filed: Jan. 15, 2016

Related U.S. Application Data
(60) Provisional application No. 62/105,315, filed on Jan. 20, 2015.

(51) Int. Cl. C08L 77/00; H01L 51/00; B32B 17/10; C08J 5/18

(52) U.S. Cl. CPC C08L 77/00; C08J 5/18; H01L 51/0035; H01L 51/0043; B32B 17/10724; H01L 51/0003; C08L 2201/56; C08L 2203/16; C08L 2203/20; C08J 2377/00; C08L 2201/10; B32B 2307/412; B32B 2457/00; H01L 51/5012

(57) ABSTRACT

In an aspect, the present disclosure relates to a polyamide solution comprising an aromatic polyamide and a solvent, wherein a Young's modulus of at least one direction of a cast film produced by casting the polyamide solution on a glass plate is 3.0 GPa or more, and a tensile strength of the cast film is 100 MPa or more and 250 MPa or less. In another aspect, the present disclosure relates to a polyamide solution comprising an aromatic polyamide and a solvent, wherein a Young's modulus of at least one direction of a cast film produced by casting the polyamide solution on a glass plate is 3.0 GPa or more, and an aromatic polyamide of the polyamide solution has a constitutional unit represented by following general formulae (I) and (II).

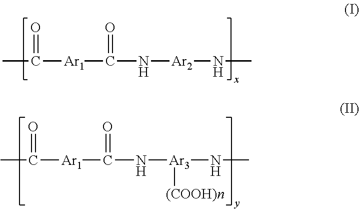

### CROSS-REFERENCE TO RELATED APPLICATIONS

The present application is based upon and claims the benefit of priority to U.S. Application No. 62/105,315, filed Jan. 20, 2015, the entire contents of which are incorporated herein by reference.

### TECHNICAL FIELD

The present disclosure, in one aspect, relates to a polyamide solution containing an aromatic polyamide and a solvent. The present disclosure, in another aspect, relates to a method for manufacturing a display element, an optical element, an illumination element, or a sensor element, the method including the step of forming a polyamide film by using the polyamide solution.

### BACKGROUND ART

As a display element is required to have transparency, a glass substrate in which a glass plate is used has been used as a substrate for the display element (JP10311987(A)). But it has been pointed out in some cases that a display element in which a glass substrate is used has problems such as a heavy weight, being easy to break, and being unbent. To cope with this, an attempt to use a transparent resin film in place of a glass substrate has been proposed.

Further, as a substrate for a sensor element used in an input device such as an image pickup device, a glass plate, an inorganic substrate made of YSZ or the like, a resin substrate, or a substrate made of a composite material of such materials, is used (JP2014-3244 (A)). A substrate for a sensor element, when provided on the light receiving section side, is required to have transparency.

As a transparent resin for optical use, polycarbonate having high transparency, or the like, has been known, but in the case where polycarbonate is used in the manufacture of a display element, there arise problems relating to heat-resisting properties and mechanical strength thereof. On the other hand, polyimide, for example, is used as a heat-resistant resin, but common polyimide has problems when used for optical use since it is colored in dark brown. Further, polyimide having a cyclic structure has been known as polyimide having transparency, but it has a problem of low heat-resisting properties.

WO 2004/039863 and JP2008260266(A) disclose, as an optical polyamide film, aromatic polyamide having diamine including a trifluoro group, which has both of high rigidity and heat-resisting properties.

WO 2012/129422 discloses a transparent polyamide film that exhibits a heat stability and a size stability. This transparent film is manufactured by casting an aromatic polyamide solution and hardening the same at a high temperature. It is disclosed that this film having been subjected to a curing treatment exhibits a transmittance of higher than 80% in a range of 400 nm to 750 nm, and a linear expansion coefficient (CTE) of less than 20 ppm/° C., thus exhibiting excellent solvent resistance. Besides, it is also disclosed that this film can be used as a flexible substrate for a microelectronics device.

### SUMMARY OF THE INVENTION

The present disclosure, in one or more embodiments, relates to a polyamide solution containing an aromatic polyamide and a solvent, wherein a Young's modulus of at least one direction of a cast film produced by casting the polyamide solution on a glass plate is 3.0 GPa or more, and a tensile strength of the cast film is 100 MPa or more and 250 MPa or less.

Further, the present disclosure, in one or more embodiments, relates to a polyamide solution containing an aromatic polyamide and a solvent,

wherein a Young's modulus of at least one direction of a cast film produced by casting the polyamide solution on a glass plate is 3.0 GPa or more, and

a polyamide of the polyamide solution has a constitutional unit represented by following general formulae (I) and (II):

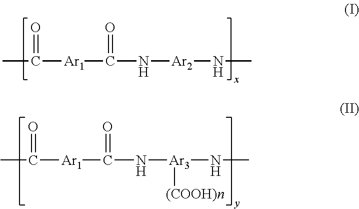

where x represents mol % of the constitutional unit of the formula (I), y represents mol % of the constitutional unit of the formula (II), x is 70 to 100 mol %, y is 0 to 30 mol %, and n is 1 to 4,

in the formula (I), Ar₁ is selected from the group comprising:

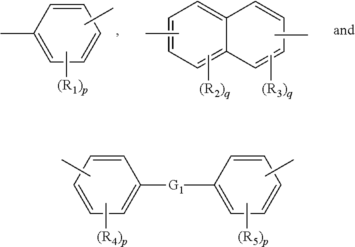

where p=4, and q=3,
R₁, R₂, R₃, R₄ and R₅ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₁ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group,

in the formula (II), Ar₂ is selected from the group comprising:

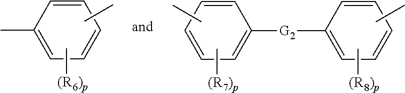

where p=4,
R₆, R₇ and R₈ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₂ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group, and

in the formula (III), Ar₃ is selected from the group comprising:

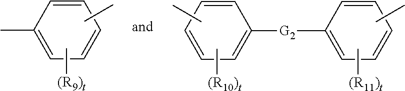

where t=0 to 3,
R₉, R₁₀ and R₁₁ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₃ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group.

Further, the present disclosure, in one or more embodiments, relates to a polyamide film obtained by casting the polyamide solution according to the present disclosure onto a base.

Further, the present disclosure, in one or more embodiments, relates to a laminated composite material, including a glass plate and a polyamide resin layer, wherein the polyamide resin layer is laminated on one surface of the glass plate, and the polyamide resin is a polyamide resin produced by casting the polyamide solution according to the present disclosure on a glass plate.

Further, the present disclosure, in one or more embodiments, relates to a method for manufacturing a display element, an optical element, an illumination element or a sensor element, comprising the steps of: a) casting the polyamide solution according to the present disclosure onto a base; b) causing a polyamide film to be formed from the casted polyamide solution on the base after the casting step (a); and c) forming the display element, the optical element, the illumination element or the sensor element, on a surface of the polyamide film.

### BRIEF DESCRIPTION OF THE DRAWINGS

FIG. 1 is a flowchart illustrating a method for manufacturing an OLED element or a sensor element according to one embodiment.

FIG. 2 is a flowchart illustrating a method for manufacturing an OLED element or a sensor element according to one embodiment.

FIG. 3 is a flowchart illustrating a method for manufacturing an OLED element or a sensor element according to one embodiment.

FIG. 4 is a schematic cross-sectional view illustrating a configuration of an organic electroluminescent (EL) element 1 according to one embodiment.

FIG. 5 is a schematic cross-sectional view illustrating a sensor element 10 according to one embodiment.

### DETAILED DESCRIPTION OF THE INVENTION

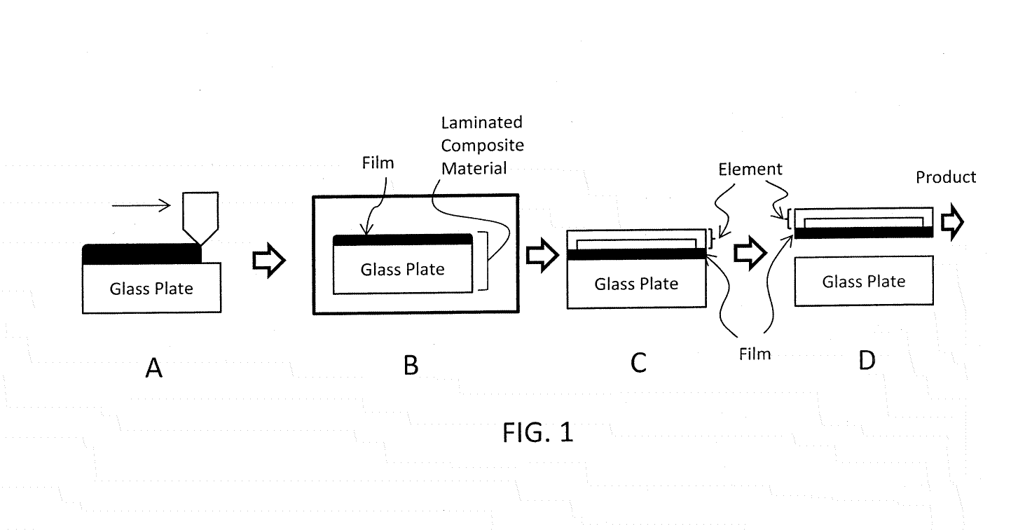

A display element, an optical element, or an illumination element such as an organic electroluminescence (OEL), or an organic light-emitting diode (OLED) is often manufactured by a process illustrated in FIG. 1. More specifically, first, a polymer solution (vanish) is casted (applied) on a glass base or a silicon wafer base (Step A). Next, the polymer solution thus casted is hardened, whereby a film is formed (Step B). On the film, an element such as an OLED or the like is formed (Step C), and thereafter, the element (product) such the OLED or the like is separated from the base (Step D). In recent years, a polyimide film is used as the film used in the steps shown in FIG. 1.

Further, a sensor element used in an input device such as an image pickup device is also often manufactured through the process as illustrated in FIG. 1. More specifically, a polymer solution (vanish) is casted (applied) on a base (glass or a silicon wafer) (Step A). Next, the polymer solution thus casted is hardened, whereby a film is formed (Step B). On the film, a sensor element is formed (Step C), and thereafter, the sensor element (product) is separated from the base (Step D).

In the method for manufacturing a display element, an optical element, an illumination element or a sensor element as illustrated in FIG. 1, it is expected that the supply of a solution of a polymer having excellent tenacity in addition to the transparency and the heat-resisting properties makes the handling of the film and the separating step easier (that is, prevents a crack from occurring in the film in the separating step), whereby the yield is improved.

In the present disclosure, a “cast film produced by casting a polyamide solution on a glass plate” refers to a film obtained by applying a polyamide solution according to the present disclosure on a flat glass substrate, drying and optionally hardening the same, in one or more embodiments. The “cast film” refers to a film produced by a film forming method disclosed in Example, in one or more embodiments. The cast film has a thickness of 7 to 12 μm, 9 to 11 μm, about 10 μm, or 10 μm, in one or more non-limited embodiments

### [Tenacity]

In the present disclosure, the improvement of the tenacity of a film refers to the improvement of at least either one of the Young's modulus and the tensile strength of the film, in one or more embodiments.

### [Young's Modulus]

A cast film produced by casting the polyamide solution according to the present disclosure on a glass plate, in one or more embodiments, has a Young's modulus in at least one direction of 3.0 GPa or more, preferably 4.0 GPa or more, and more preferably 5.0 GPa or more, from the viewpoint of using the cast film in the manufacture of an electronic component such as a display element, an optical element, an illumination element, or a sensor element. From the Young's modulus is, from the same viewpoint, preferably 10.0 GPa or less, more preferably 8.0 GPa or less, and further preferably 7.0 GPa or less.

The “Young's modulus of at least one direction of a cast film” can be measured by a method described in the descriptions of Example.

### [Tensile Strength]

A cast film produced by casting the polyamide solution according to the present disclosure on a glass plate, in one or more embodiments, has a tensile strength of preferably 100 MPa or more, more preferably 120 MPa or more, further preferably 140 MPa or more, still further preferably 150 MPa or more, and still further preferably 180 MPa, from the viewpoint of using the cast film in the manufacture of an electronic component such as a display element, an optical element, an illumination element, or a sensor element. The tensile strength is preferably 250 MPa or less, and more preferably 230 MPa or less, from the same viewpoint. The tensile strength is, from the same viewpoint, preferably 100 MPa to 250 MPa both inclusive, more preferably 120 MPa to 250 MPa both inclusive, further preferably 140 MPa to 250 MPa both inclusive, still further preferably 150 MPa to 250 MPa both inclusive, still further preferably 180 MPa to 250 MPa both inclusive, and still further preferably 180 MPa to 230 MPa both inclusive.

The “tensile strength of a cast film” can be measured by a method described in the descriptions of Example.

Aromatic polyamide in the polyamide solution according to the present disclosure, in one or more embodiments, is preferably such that at least one of constitutional units composing aromatic polyamide has a free carboxyl group, from the viewpoint of using the cast film in the manufacture of an electronic component such as a display element, an optical element, an illumination element, or a sensor element.

Examples of aromatic polyamide in the polyamide solution according to the present disclosure, in one or more embodiments, include aromatic polyamide having a repetitive unit represented by general formulae (I) and (II) below:

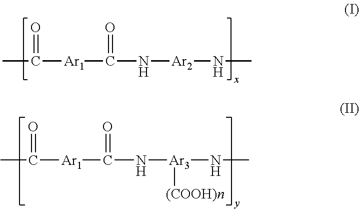

Here, x represents a mole percentage of the constitutional units of the formula (I), which is 70 to 100 mol %, y represents a mole percentage of the constitutional units of the formula (II), which is 0 to 30 mol %, and n is 1 to 4.

In the Formulae (I) and (II), Ar₁ is selected from the group consisting of the following:

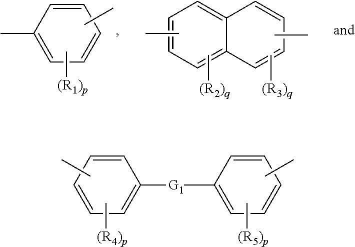

Here, p=4, q=3, and R₁, R₂, R₃, R₄, and R₅ are selected from the group consisting of hydrogen, halogen (fluoride, chloride, bromide, and iodide), an alkyl group, a substituted alkyl group such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these. The R₁s may be different from one another, the R₂s may be different from one another, the R₃s may be different from one another, the R₄s may be different from one another, and the R₅s may be different from one another. G₁ is selected from the group consisting of a covalent bond, a CH₂ group, a C(CH₃)₂ group, a C(CF₃)₂ group, a C(CX₃)₂ group (where X is halogen (fluoride, chloride, bromide, and iodide)), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene).

In Formula (I), Ar₂ is selected from the group consisting of the following:

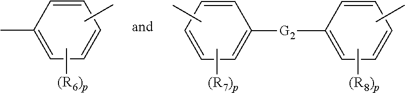

Here, p=4, and R₆, R₇, and R₈ are selected from the group consisting of hydrogen, halogen (fluoride, chloride, bromide, and iodide), alkyl, substituted alkyl such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these. The R₆s may be different from one another, the R₇s may be different from one another, and the R₈s may be different from one another. G₂ is selected from the group consisting of a covalent bond, a CH₂ group, a C(CH₃)₂ group, a C(CF₃)₂ group, a C(CX₃)₂ group (where X is halogen), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene).

In Formula (II), Ar₃ is selected from the group consisting of the following:

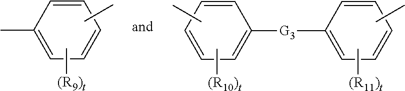

Here, t=0 to 3, and R₉, R₁₀, and R₁₁ are selected from the group consisting of hydrogen, halogen (fluoride, chloride, bromide, and iodide), alkyl, substituted alkyl such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these. The R₉s may be different from one another, the R₁₀s may be different from one another, and the R₁₁s may be different from one another. G₃ is selected from the group consisting of a covalent bond, a CH₂ group, a C(CH₃)₂ group, a C(CF₃)₂ group, a C(CX₃)₂ group (where X is halogen), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene).

In one or more embodiments of the present disclosure, Formulae (I) and (II) are selected in such a manner that the polyamide can be dissolved in a polar solvent or a mixture solvent containing one or more polar solvents. In one or more embodiments of the present disclosure, x in the repetitive structure (I) is 70.0 to 99.99 mol %, and y in the repetitive structure (II) is 30.0 to 0.01 mol %. In one or more embodiments of the present disclosure, x in the repetitive structure (I) is 90.0 to 99.99 mol %, and y in the repetitive structure (II) is 10.0 to 0.01 mol %. In one or more embodiments of the present disclosure, x in the repetitive structure (I) is 90.1 to 99.9 mol %, and y in the repetitive structure (II) is 9.9 to 0.1 mol %. In one or more embodiments of the present disclosure, x in the repetitive structure (I) is 91.0 to 99.0 mol %, and y in the repetitive structure (II) is 9.0 to 1.0 mol %. In one or more embodiments of the present disclosure, x in the repetitive structure (I) is 92.0 to 98.0 mol %, and y in the repetitive structure (II) is 8.0 to 2.0 mol %. In one or more embodiments of the present disclosure, Ar₁, Ar₂, and Ar₃ include a plurality of identical or different repetitive structures (I) and (II).

In one or more embodiments, the polyamide solution according to the present disclosure is, for example, a polyamide solution that is obtained or can be obtained by a manufacturing method including the following steps, form the viewpoint of using the film in a display element, an optical element, an illumination element, or a sensor element. The polyamide solution according to the present disclosure, however, is not limited to those manufactured by the manufacturing method including the following steps.

a) Dissolving an aromatic diamine in a solvent;

b) Causing the aromatic diamine and an aromatic diacid dichloride to react with each other, so as to generate hydrochloric acid and a polyamide solution;

c) Removing the hydrochloric acid, which is free, by causing the free hydrochloric acid to react with a trapping reagent.

In one or more embodiments of a method for manufacturing a polyamide solution according to the present disclosure, the aromatic diacid dichlorides include aromatic dicarboxylic acid dichlorides expressed by the following general structural formulae;

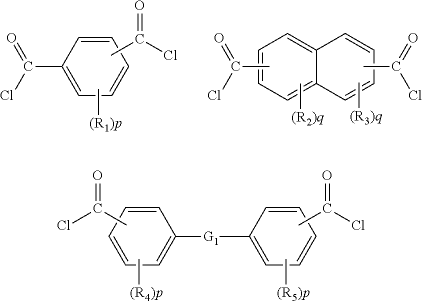

[p=4, q=3, and R₁, R₂, R₃, R₄, and R₅ are selected from the group consisting of hydrogen, halogen (fluoride, chloride, bromide, and iodide), alkyl, substituted alkyl such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these. The R₁s may be different from one another, the R₂s may be different from one another, the R₃s may be different from one another, the R₄s may be different from one another, and the R₅s may be different from one another. G₁ is selected from the group consisting of a covalent bond, a CH₂ group, a C(CH₃)₂ group, a C(CF₃)₂ group, a C(CX₃)₂ group (where X is halogen), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene).]

Examples of the aromatic diacid dichloride used in the method for manufacturing a polyamide solution according to the present disclosure include the following, in one or more embodiments, from the viewpoint of using the film in a display element, an optical element, an illumination element, or a sensor element:

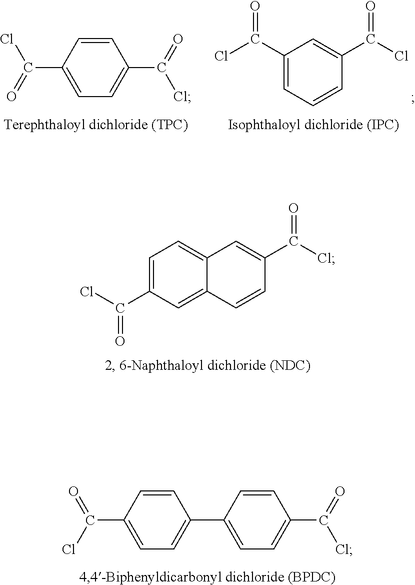 [SMILES: O=C(Cl)c1ccc(C(=O)Cl)cc1 ; O=C(Cl)c1cccc(C(=O)Cl)c1 ; O=C(Cl)c1ccc2cc(C(=O)Cl)ccc2c1 ; O=C(Cl)c1ccc(-c2ccc(C(=O)Cl)cc2)cc1]

In one or more embodiments, the polyamide solution according to the present disclosure is such that the diacid dichloride monomer represented by the formula (III) below makes up in total preferably 90 mol % or less, more preferably 65 mol % or less, further preferably 45 mol % or less, still further preferably 35 mol % or less, and still further preferably 30 mol % or less, of an entirety of diacid dichloride monomers used synthesis, from the viewpoint of using the polyamide solution in the manufacture of an electronic component such as a display element, an optical element, an illumination element, or a sensor element, and from the viewpoint of improving the tenacity of the cast film:

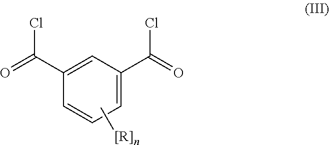

[In Formula (III), n=4, and R is independently selected from the group consisting of hydrogen, halogen, alkyl, substituted alkyl, a nitro group, a cyano group, a thioalkyl group, an alkoxy group, a substituted alkoxy group, an aryl group, a substituted aryl group, an alkyl ester group, and a substituted alkyl ester group, as well as combinations of these.]

In one or more embodiments, from the same viewpoint, the polyamide solution according to the present disclosure is such that the diacid dichloride monomer represented by Formula (III) makes up in total preferably 15 mol % or more and 45 mol % or less, and more preferably 20 mol % or more and 40 mol % or less.

In one or more embodiments of the method for manufacturing a polyamide solution according to the present disclosure, aromatic diacid diamines include those represented by the following general structural formulae;

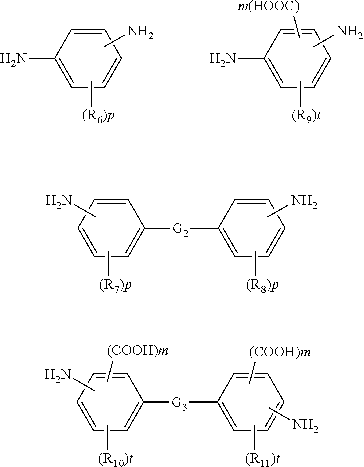

[p=4, m=1 or 2, and t=1 to 3, as well as R₆, R₇, R₈, R₉, R₁₀, and R₁₁ are selected from the group consisting of hydrogen, halogen (fluoride, chloride, bromide, and iodide), alkyl, substituted alkyl such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these. The R₆s may be different from one another, the R₇s may be different from one another, the R₆s may be different from one another, the R₉s may be different from one another, the R₁₀s may be different from one another, and the R₁₁s may be different from one another. G₂ and G₃ are selected from the group consisting of a covalent bond, a CH₂ group, a C(CH₃)₂ group, a C(CF₃)₂ group, a C(CX₃)₂ group (where X is halogen), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene).]

Examples of aromatic diamine used in the method for manufacturing a polyamide solution according to the present disclosure include the following in one or more embodiments:

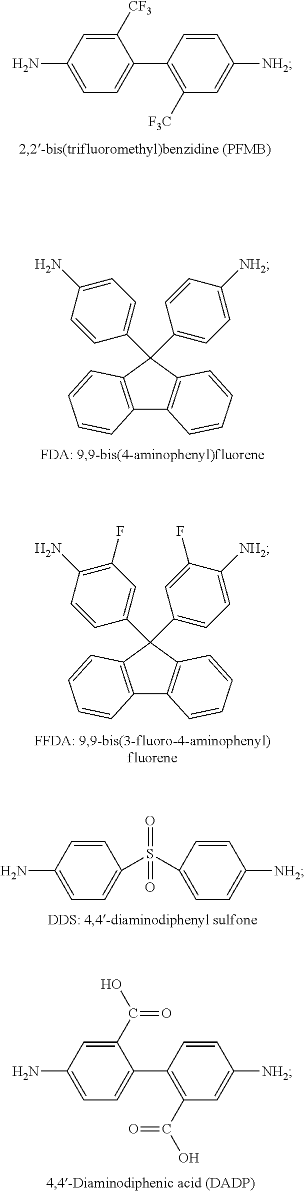 [SMILES: Nc1ccc(-c2ccc(N)cc2C(F)(F)F)c(C(F)(F)F)c1 ; Nc1ccc(C2(c3ccc(N)cc3)c3ccccc3-c3ccccc32)cc1 ; Nc1ccc(C2(c3ccc(N)c(F)c3)c3ccccc3-c3ccccc32)cc1F ; Nc1ccc(S(=O)(=O)c2ccc(N)cc2)cc1 ; Nc1ccc(-c2ccc(N)cc2C(=O)O)c(C(=O)O)c1]

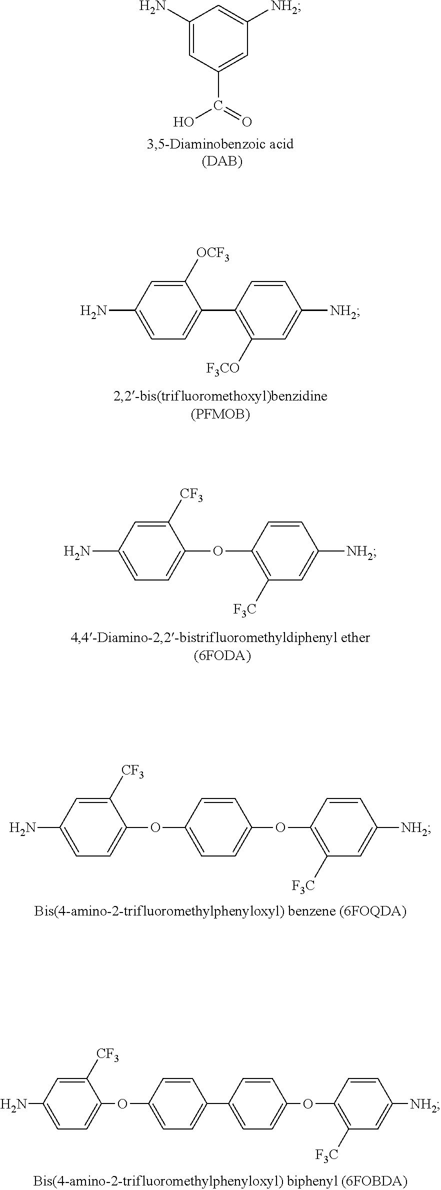 [SMILES: Nc1cc(N)cc(C(=O)O)c1 ; Nc1ccc(-c2ccc(N)cc2OC(F)(F)F)c(OC(F)(F)F)c1 ; Nc1ccc(Oc2ccc(N)cc2C(F)(F)F)c(C(F)(F)F)c1 ; Nc1ccc(Oc2ccc(Oc3ccc(N)cc3C(F)(F)F)cc2)c(C(F)(F)F)c1 ; Nc1ccc(Oc2ccc(-c3ccc(Oc4ccc(N)cc4C(F)(F)F)cc3)cc2)c(C(F)(F)F)c1]

In one or more embodiments of the method for manufacturing a polyamide solution according to the present disclosure, polyamide is produced by condensation polymerization in a solvent, and hydrochloric acid generated during the reaction is captured by a reagent such as propylene oxide (PrO).

In one or more embodiments of the present disclosure, a volatile product is formed by reaction between a trapping reagent and hydrochloric acid, from the viewpoint of using the polyamide solution in the manufacture of a display element, an optical element, an illumination element, or a sensor element.

In one or more embodiments of the present disclosure, from the viewpoint of using the polyamide solution in the manufacture of a display element, an optical element, an illumination element, or a sensor element, the trapping reagent is propylene oxide (PrO). In one or more embodiments of the present disclosure, before or during the reaction step (b), the reagent is added to the mixture. By adding the reagent before for during the reaction step (b), the degree of viscosity and the generation of lumps in the mixture after the reaction step (b) can be reduced, whereby the productivity of the polyamide solution can be improved. In a case where the reagent is an organic reagent such as propylene oxide, these effects are increased particularly.

In one or more embodiments of the present disclosure, from the viewpoint of increasing the heat resistance properties of the polyamide film, the method for manufacturing a polyamide solution further includes the step of end-capping one or both of a —COOH group and an —NH₂ group of terminals of the polyamide. In a case where a terminal of polyamide is —NH₂, polymerized polyamide is caused to react with benzoyl chloride, and in a case where a terminal of polyamide is —COOH, polymerized polyamide is caused to react with aniline, whereby the terminal of polyamide can be end-capped, though the end-capping method is not limited to this.

In one or more embodiments of the present disclosure, from the viewpoint of using the polyamide solution in the manufacture of a display element, an optical element, an illumination element, or a sensor element, polyamide is first separated from a polyamide solution by precipitating polyamide and again dissolving the same in a solvent (hereinafter also referred to as reprecipitation). Reprecipitation can be performed by a usual method, and in one or more embodiments, for example, polyamide is added to methanol, ethanol, isopropyl alcohol, or the like so as to be precipitated, and is washed and dissolved in a solvent.

In one or more embodiments of the present disclosure, from the viewpoint of using the polyamide solution in the manufacture of a display element, an optical element, an illumination element, or a sensor element, the polyamide solution according to the present disclosure is manufactured in the absence of an inorganic salt.

From the viewpoint of using the film in a display element, an optical element, an illumination element, or a sensor element, and from the viewpoint of suppressing whitening, in one or more embodiments, the molecular weight distribution (=Mw/Mn) of the aromatic polyamide in the polyamide solution according to the present disclosure is preferably 5.0 or less, 4.0 or less, or 3.5 or less. Further, from the same viewpoint, the molecular weight distribution of the aromatic polyamide, in one or more embodiments, is 2.0 or more.

From the viewpoint of using the film in a display element, an optical element, an illumination element, or a sensor element, in one or more embodiments, the polyamide solution according to the present disclosure is a polyamide solution having been subjected to the step of reprecipitation after synthesis of the polyamide.

From the viewpoint of using the film in a display element, an optical element, an illumination element, or a sensor element, in one or more embodiments, the polyamide solution according to the present disclosure may be such that the monomers used for synthesis of the polyamide may include a carboxyl group containing diamine monomer. In this case, the carboxyl group containing diamine monomer component makes up in total 30 mol % or less, 20 mol % or less, or 1 to 10 mol % of the total amount of the monomers, in one or more embodiments.

### [Solvent]

In one or more embodiments of the present disclosure, from the viewpoint of increasing the solubility of the polyamide in a solvent, the solvent is a polar solvent or a mixture solvent containing one or more polar solvents. In one embodiment, from the viewpoint of increasing the solubility of the polyamide in a solvent, the polar solvent is methanol, ethanol, propanol, isopropanol (IPA), butanol, acetone, methyl ethyl ketone (MEK), methyl isobutyl ketone (MIBK), toluene, cresol, xylene, propylene glycol monomethyl ether acetate (PGMEA), N,N-dimethylacetamide (DMAc), N-methyl-2-pyrrolidone (NMP), dimethyl sulfoxide (DMSO), butyl cellosolve, γ-butyrolactone, α-methyl-γ-butyrolactone, methyl cellosolve, ethyl cellosolve, ethylene glycolmonobutyl ether, diethylene glycolmonobutyl ether, N,N-dimethyl formamide (DMF), 3-methoxy-N,N-dimethylpropionamide, 3-butoxy-N,N-dimethyl propane amide, 1-ethyl-2-pyrrolidone, N,N-dimethylpropionamide, N,N-dimethyl butyl amide, N,N-diethylacetamide, N,N-diethyl propionamide, 1-methyl-2-piperidinone, propylene carbonate, or a combination of any of these, or alternatively, a mixture solvent containing at least one of the above-described solvents.

### [Polyamide Content]

From the viewpoint of using the film in a display element, an optical element, an illumination element, or a sensor element, in one or more embodiments, the content of aromatic polyamide in the polyamide solution according to the present disclosure is, for example, 2% by weight or more, 3% by weight or more, or 5% by weight or more, and from the same viewpoint, it is, for example, 30% by weight or less, 20% by weight or less, or 15% by weight or less.

### [Multifunctional Epoxide]

From the viewpoint of lowering a hardening temperature when a cast film is formed and improving the resistance of the film against an organic solvent, in one or more embodiments, the polyamide solution according to the present disclosure may further contain a multifunctional epoxide. In the present disclosure, the “multifunctional epoxide” refers to an epoxide having 2 or more epoxy groups. In a case where the polyamide solution according to the present disclosure contains a multifunctional epoxide, the content of the multifunctional epoxide is, for example, about 0.1 to 10% by weight with respect to the weight of the polyamide, in one or more embodiments.

Regarding the polyamide solution according to the present disclosure containing a multifunctional epoxide, in one or more embodiments, the hardening temperature for the same can be lowered, and in one or more non-limited embodiments, the film hardening temperature can be set to about 200° C. to about 300° C. Further, with the polyamide solution according to the present disclosure containing a multifunctional epoxide, in one or more embodiments, the resistance against an organic solvent can be imparted to a film formed with the polyamide solution. Examples of the organic solvent include polar solvents such as N-methyl-2-pyrrolidone (NMP), N,N-dimethyl acetamide (DMAc), dimethyl sulfoxide (DMSO), and γ-butyrolactone.

It is estimated that the effects of the lowering of the hardening temperature and the improvement of the resistance against an organic solvent, achieved by the polyamide solution according to the present disclosure containing a multifunctional epoxide, attribute to the cross-linking of the epoxide. From the viewpoint of promoting the cross-linking of the epoxide, polyamide of the polyamide solution according to the present disclosure containing a multifunctional epoxide, in one or more embodiments, preferably has a free pendant carboxy group in the main chain thereof, or preferably is synthesized by using a diamine monomer having a carboxy group.

From the viewpoint of lowering the hardening temperature and improving the resistance against an organic solvent, in one or more embodiments, examples of the multifunctional epoxide include epoxides having two or more glycidyl groups, or epoxides having two or more alicyclic structures. Further, the multifunctional epoxide is, for example, one selected from the group consisting of those represented by the following formulae (I) to (IV):

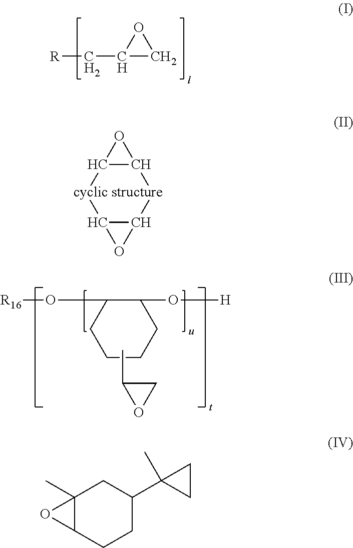

In the formula (I), I represents the number of glycidyl groups, and R is selected from the group consisting of the following, and combinations of the same:

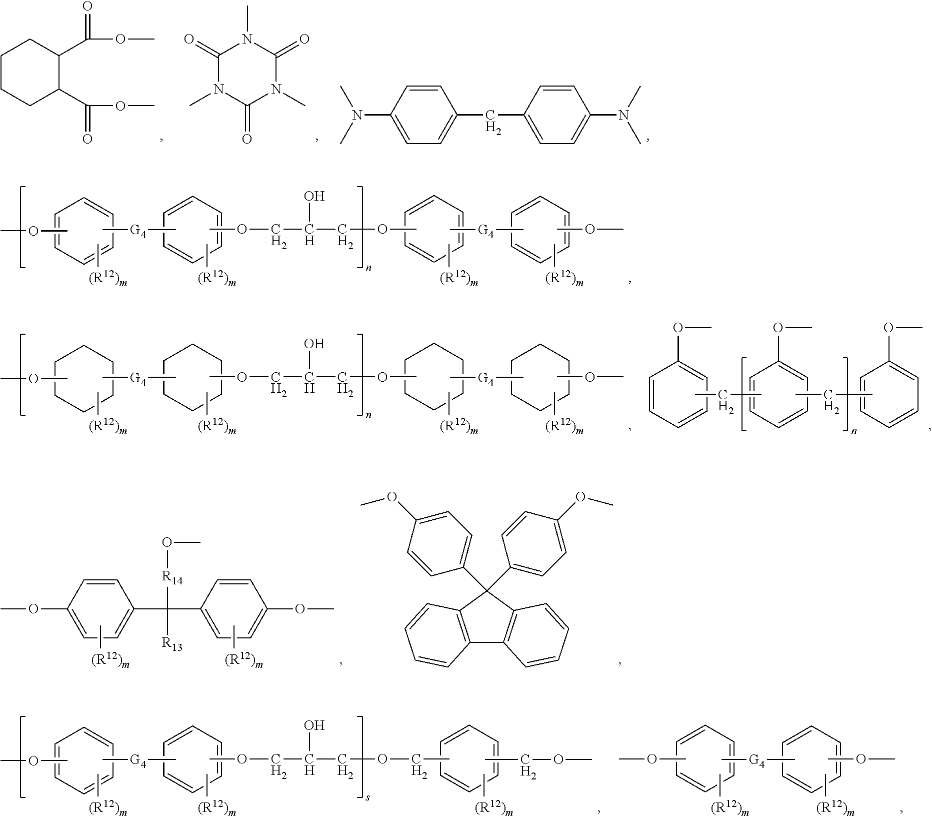

where m is 1 to 4, n and s represent average numbers of units, which are independently 0 to 30; R₁₂ is hydrogen, halogen (fluoride, chloride, bromide, and iodide), alkyl, substituted alkyl such as alkyl halide, a nitro group, a cyano group, a thioalkyl group, an alkoxy group, a substituted alkoxy group such as alkoxy halide, an aryl group, a substituted aryl group such as aryl halide, an alkyl ester group, and a substituted alkyl ester group such as a halogenated alkyl ester group, as well as combinations of these; G₄ is selected from the group consisting of a covalent bond, a CH₂ group, a C(CH₃)₂ group, a C(CF₃)₂ group, a C(CX₃)₂ group (where X is halogen), a CO group, an O atom, an S atom, an SO₂ group, an Si(CH₃)₂ group, a 9,9-fluorene group, a substituted 9,9-fluorene, and an OZO group (where Z represents an aryl group or a substituted aryl group such as a phenyl group, a biphenyl group, a perfluoro biphenyl group, a 9,9-bis(phenyl)fluorene group, or a substituted 9,9-bis(phenyl)fluorene); R₁₃ is hydrogen or a methyl group; and R₁₄ is a divalent organic group.

In the formula (II), the cyclic structure is selected from the group consisting of the following cyclic structures, and combinations of the same:

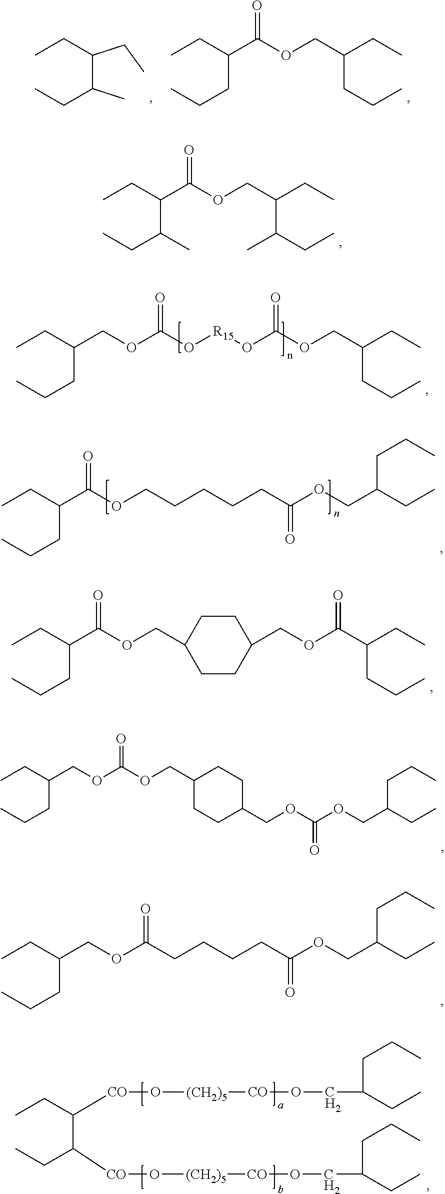

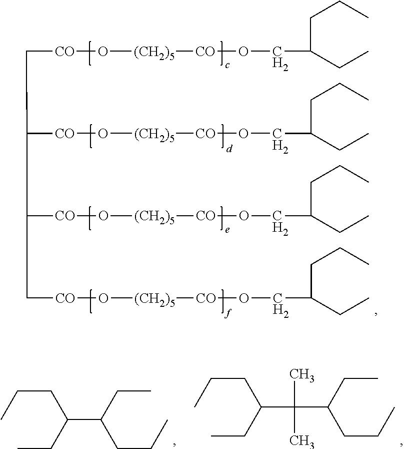

where R₁₅ is an alkyl chain having 2 to 18 carbon atoms, which may be a straight chain, a branched chain, or a chain having a cycloalkane structure; m and n represent average numbers of units, which are independently 1 to 30; and a, b, c, d, e, and f are independently 0 to 30.

In the formula (III), R₁₆ is an alkyl chain having 2 to 18 carbon atoms, which may be a straight chain, a branched chain, or a chain having cycloalkane, t and u represent average numbers of units, which are independently 1 to 30.

Examples of the multifunctional epoxide to be contained in the polyamide solution according to the present disclosure include the following:

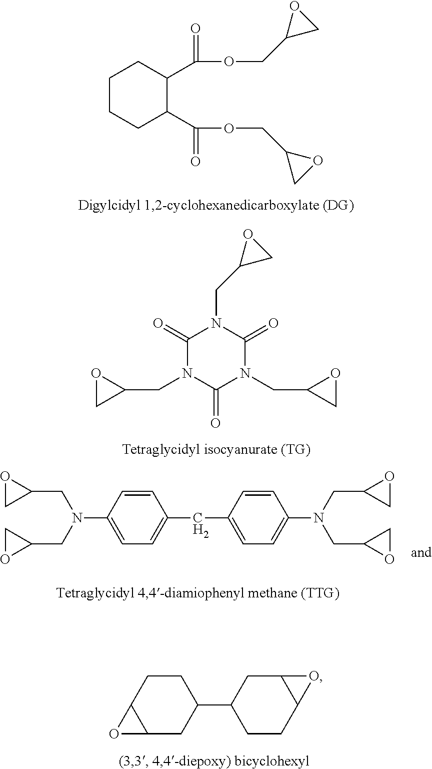 [SMILES: O=C(OCC1CO1)C1CCCCC1C(=O)OCC1CO1 ; O=c1n(CC2CO2)c(=O)n(CC2CO2)c(=O)n1CC1CO1 ; c1cc(N(CC2CO2)CC2CO2)ccc1Cc1ccc(N(CC2CO2)CC2CO2)cc1 ; C1CC2OC2CC1C1CCC2OC2C1]

and further include the following as well:

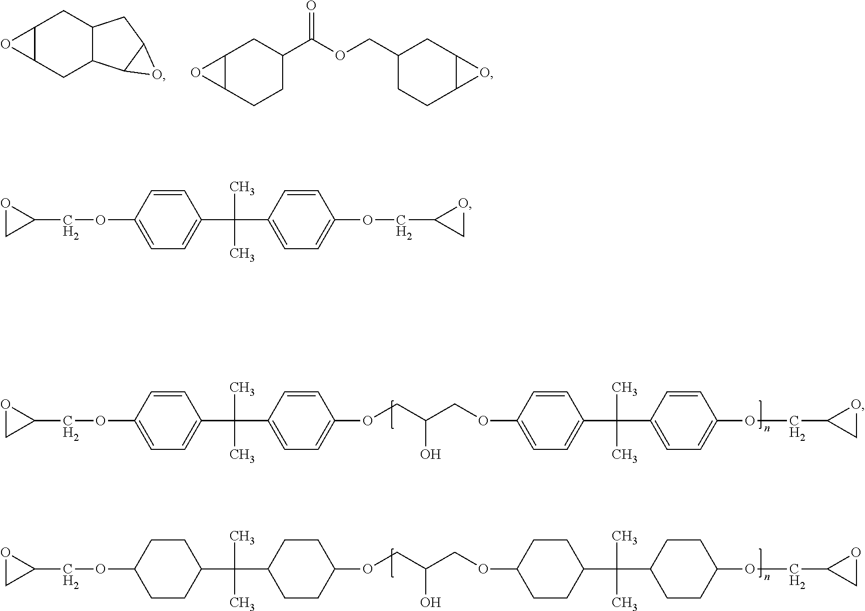

The polyamide solution according to the present disclosure, in one or more embodiments, is a polyamide solution for use in a method for manufacturing a display element, an optical element, an illumination element or a sensor element, including the following steps a) to c):

a) casting the polyamide solution onto a base;

b) causing the casted polyamide solution to be formed into a polyamide film on the base after the casting step (a); and

c) forming the display element, the optical element, the illumination element or the sensor element on a surface of the polyamide film.

Here, the base or the surface of the base is a surface of glass or a silicon wafer. Further, examples of the casting in the step a), in one or more embodiments, include application, and as application, various types of liquid phase film forming methods such as the die coating method, the ink-jet method, the spin coating method, the bar coating method, the roll coating method, the wire bar coating method, and the dip coating method can be used.

### [Film]

The present disclosure, in one aspect, relates to a polyamide film obtained by casting the polyamide solution according to the present disclosure onto a base.

### [Laminated Composite Material]

In the present disclosure, the “laminated composite material” refers to a material obtained by laminating a glass plate and a polyamide resin layer on each other. The phrase of laminating a glass plate and a polyamide resin layer on each other, in one or more non-limited embodiments, means laminating a glass plate and a polyamide resin layer directly on each other, and further, in one or more non-limited embodiments, means laminating a glass plate and a polyamide resin layer on each other with one or more layers being interposed therebetween. In the present disclosure, therefore, the laminated composite material, in one or more embodiments, includes a glass plate and a polyamide resin layer, wherein the polyamide resin is laminated on one of surfaces of the glass plate.

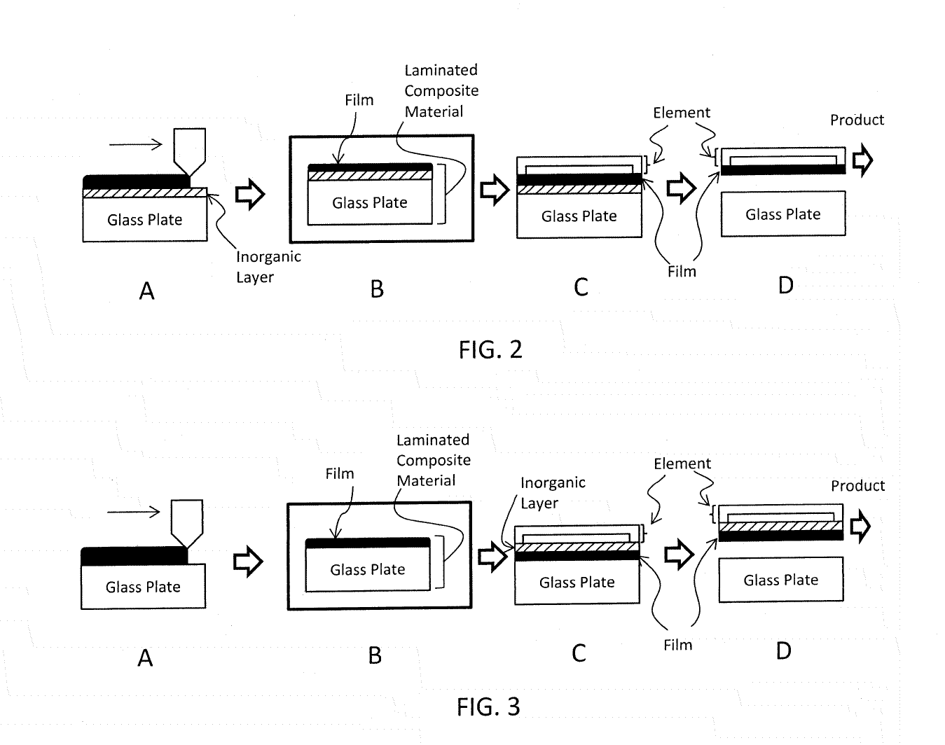

The laminated composite material according to the present disclosure, in one or more non-limited embodiments, can be used in the method for manufacturing a display element, an optical element, an illumination element, or a sensor element, a typical example of which is illustrated in FIG. 1, and further, in one or more non-limited embodiments, the laminated composite material can be used as a laminated composite material obtained by the step B of the manufacturing method illustrated in FIG. 2. The laminated composite material according to the present disclosure, therefore, in one or more non-limited embodiments, is a laminated composite material for use in the method for manufacturing a display element, an optical element, an illumination element, or a sensor element including the step of forming the display element, the optical element, the illumination element, or the sensor element on a surface of the polyamide resin layer on an opposite side with respect to the surface thereof facing the glass plate.

The laminated composite material according to the present disclosure may further include an organic resin layer and/or an inorganic layer in addition to the polyamide resin layer. Examples of the additional organic resin layer, in one or more non-limited embodiments, include a flattening coat layer.

Examples of the inorganic layer, one or more non-limited embodiments, include a gas barrier layer that prevents permeation of water or oxygen, and a buffer coating layer that prevents ion migration to TFT elements.

One or more non-limited embodiments in which an inorganic layer is formed between a glass plate and a polyamide resin layer is illustrated in FIG. 2. Examples of the inorganic layer in the present embodiment include an amorphous Si layer formed on the glass plate. In Step A, on the amorphous Si layer on the glass plate, a polyamide vanish is applied, and in Step B, the vanish is dried and/or hardened, whereby a laminated composite material is formed. In Step C, on the polyamide resin layer (polyamide film) on the laminated composite material, a display element, an optical element, an illumination element, or a sensor element is formed. In step D, the amorphous Si layer is irradiated with laser, and the display element, the optical element, the illumination element, or the sensor element (including the polyamide resin layer) as a product is separated from the glass plate.

One or more non-limited embodiments in which an inorganic layer is formed on a surface of the polyamide resin layer on an opposite side with respect to the surface thereof facing the glass plate is illustrated in FIG. 3. The inorganic layer in the present embodiment is, for example, an inorganic barrier layer. In Step A, a polyamide vanish is applied on a glass plate, and in Step B, the vanish is dried and/or hardened, whereby a laminated composite material is formed. Here, an inorganic layer is additionally formed on the polyamide resin layer (polyamide film). In one or more non-limited embodiments, the laminated composite material including the inorganic layer is regarded as the laminated composite material according to the present disclosure (FIG. 3, Step C). A display element, an optical element, an illumination element, or a sensor element is formed on this inorganic layer. In step D, the polyamide resin layer is separated, whereby the display element, the optical element, the illumination element, or the sensor element (including the polyamide resin layer) as a product is obtained.

### [Polyamide Resin Layer]

The polyamide resin of the polyamide resin layer in the laminated composite material according to the present disclosure can be formed with use of the polyamide solution according to the present disclosure.

### [Thickness of Polyamide Resin Layer]

From the viewpoint of using the film in a display element, an optical element, an illumination element, or a sensor element, and from the viewpoint of suppressing occurrence of a crack in the resin layer, in one or more embodiments, the polyamide resin layer in the laminated composite material according to the present disclosure has a thickness of, for example, 500 μm or less, 200 μm or less, or alternatively, 100 μm or less. Further, in one or more non-limited embodiments, the polyamide resin layer has a thickness of, for example, 1 μm or more, 2 μm or more, or alternatively, 3 μm or more.

### [Transmittance of Polyamide Resin Layer]

From the viewpoint of using the laminated composite material suitably in the manufacture of a display element, an optical element, an illumination element, or a sensor element, in one or more embodiments, the polyamide resin layer in the laminated composite material according to the present disclosure has a total light transmittance of 70% or more, 75% or more, or 80% or more.

### [Glass Plate]

From the viewpoint of using the film in a display element, an optical element, an illumination element, or a sensor element, in one or more embodiments, examples of the material for the glass plate in the laminated composite material according to the present disclosure include soda lime glass, and non-alkali glass.

From the viewpoint of using the film in a display element, an optical element, an illumination element, or a sensor element, in one or more embodiments, the glass plate in the laminated composite material according to the present disclosure has a thickness of, for example, 0.3 mm or more, 0.4 mm or more, or alternatively, 0.5 mm or more. Further, in one or more embodiments, the glass plate has a thickness of, for example, 3 mm or less, or 1 mm or less.

### [Method for Manufacturing Laminated Composite Material]

The laminated composite material according to the present disclosure can be manufactured by applying the polyamide solution according to the present disclosure to a glass plate, drying the same, and hardening the same as required.

In one or more embodiments of the present disclosure, a method for manufacturing the laminated composite material according to the present disclosure includes the following steps:

a) applying an aromatic polyamide solution on a base (glass plate); and

b) after the step a), heating the casted polyamide solution, so as to form a polyamide film.

In one or more embodiments of the present disclosure, from the viewpoint of suppressing curved deformation (warpage) and/or achieving size stability, the heating is performed in a temperature range from the boiling point of the solvent plus about 40° C. to the foregoing boiling point of the solvent plus about 100° C., preferably in a temperature range from the boiling point of the solvent plus about 60° C. to the foregoing boiling point of the solvent plus about 80° C., more preferably at a temperature of the boiling point of the solvent plus about 70° C. In one or more embodiments of the present disclosure, from the viewpoint of suppressing curved deformation (warpage) and/or achieving size stability, the heating temperature in the step (b) is between about 200° C. to 250° C. In one or more embodiments of the present disclosure, from the viewpoint of suppressing curved deformation (warpage) and/or achieving size stability, the heating time is more than about 1 minute and less than about 30 minutes.

The method for manufacturing the laminated composite material may include a curing treatment step (c) of hardening the polyamide film, after Step (b). The temperature of the curing treatment is, though depending on the capability of a heating device, in one or more embodiments, 220 to 420° C., 280 to 400° C., 330 to 370° C., 340° C. or higher, or alternatively, 340 to 370° C. Further, the duration of the curing treatment is, in one or more embodiments, 5 to 300 minutes, or 30 to 240 minutes.

### [Method for Manufacturing Display Element, Optical Element, or Illumination Element]

The present disclosure, in one aspect, relates to a method for manufacturing a display element, an optical element, or an illumination element, the method including the step of forming the display element, the optical element, or the illumination element on a surface of the organic resin layer of the laminated composite material according to the present disclosure, the surface being on an opposite side with respect to the surface thereof facing the glass plate. The manufacturing method, in one or more embodiments, further includes the step of separating the formed display element, optical element, or illumination element from the glass plate.

### [Display Element, Optical Element, or Illumination Element]

In the present disclosure, “a display element, an optical element, or an illumination element” refers to an element that composes a display body (display device), an optical device, or an illumination device, that is, for example, an organic electroluminescent (EL) element, a liquid crystal element, an organic EL illumination, or the like. Further, a thin film transistor (TFT) element, a color filter element, and the like, which composes a part of the element, are also encompassed therein. The display element, the optical element, or the illumination element according to the present disclosure, in one or more embodiments, can encompass those which can be manufactured by using the polyamide solution according to the present disclosure, those in which the polyamide film according to the present disclosure is used as a substrate of the display element, the optical element, or the illumination element.

### <One Non-Limited Embodiment of Organic EL Element>

Hereinafter one embodiment of an organic EL element, which is an embodiment of the display element according to the present disclosure, is described with reference to the drawings.

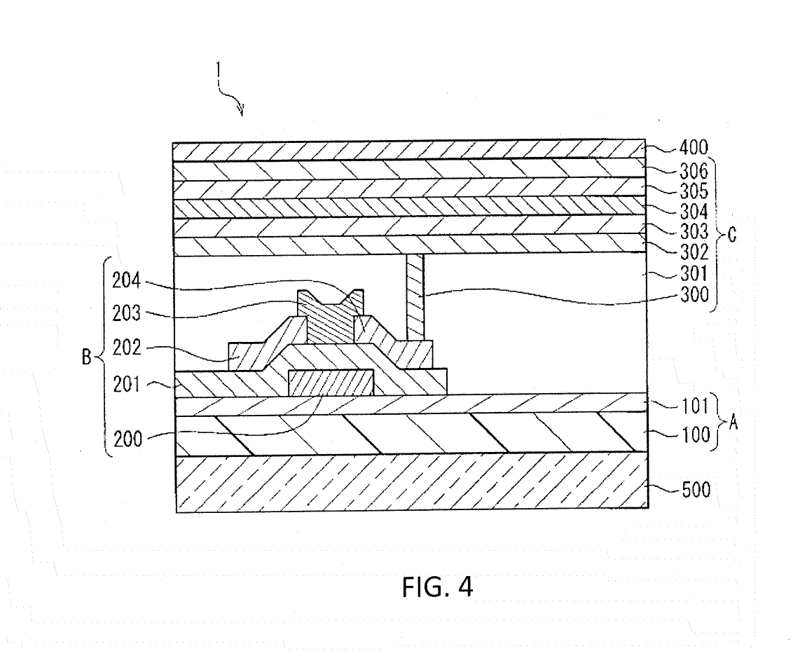

FIG. 4 is a schematic cross-sectional view illustrating an organic EL element 1 according to one embodiment. The organic EL element 1 includes a thin film transistor B and an organic EL layer C formed on a substrate A. The entirety of the organic EL element 1 is covered with a sealing member 400. The organic EL element 1 may be separated from a base 500, or may include the base 500. Hereinafter, each configuration is described in detail.

### 1. Substrate A

The substrate A includes a transparent resin substrate 100, and a gas barrier layer 101 formed on a top surface of the transparent resin substrate 100. Here, the transparent resin substrate 100 is the polyamide film according to the present disclosure.

The transparent resin substrate 100 may be annealed with heat. This is effective in eliminating distortion of the substrate, reinforcing the stability of dimensions against environmental changes, and the like.

The gas barrier layer 101 is a thin film made of SiOx, SiNx, or the like, and is formed by a vacuum film forming method such as the sputtering method, the CVD method, or the vacuum vapor deposition method. The gas barrier layer 101 has a thickness of about 10 nm to 100 nm typically, though the thickness is not limited to this. Here, the gas barrier layer 101 may be formed on a surface opposite to the surface where the gas barrier layer 101 is formed in FIG. 4, or may be formed on both of the surfaces.

### 2. Thin Film Transistor

The thin film transistor B includes a gate electrode 200, a gate insulation film 201, a source electrode 202, an active layer 203, and a drain electrode 204. The thin film transistor B is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. The method for forming the transparent thin films is, for example, the sputtering method, the vacuum vapor deposition method, or the ion plating method. Each of these electrode has a film thickness of about 50 nm to 200 nm, typically, but the thickness of the same is not limited to this.

The gate insulation film 201 is a transparent insulation thin film made of SiO₂, Al₂O₃, or the like, by the sputtering method, the CVD method, the vacuum vapor deposition method, the ion plating method, or the like. The gate insulation film 201 has a film thickness of about 10 nm to 1 μm, typically, but the thickness of the same is not limited to this.

The active layer 203 is made of, for example, monocrystalline silicon, low-temperature polysilicon, amorphous silicon, oxide semiconductor, or the like, among which an optimal one is used as required. The active layer is formed by the sputtering method or the like.

### 3. Organic EL Layer

The organic EL layer C includes a conductive connection part 300, a flattening layer 301 that is insulative, a lower electrode 302 that is an anode of an organic EL element 1, a hole transport layer 303, a light emission layer 304, an electron transport layer 305, and an upper electrode 306 that is a cathode of the organic EL element 1. The organic EL layer C is formed at least above the gas barrier layer 101 or the thin film transistor B, and the lower electrode 302 and the drain electrode 204 of the thin film transistor B are electrically connected with each other via the connection part 300. In place of this configuration, the lower electrode 302 and the source electrode 202 of the thin film transistor B may be connected with each other via the connection part 300.

The lower electrode 302 is an anode of the organic EL element 1, and is a transparent thin film made of indium tin oxide (ITO), indium zinc oxide (IZO), zinc oxide (ZnO), or the like. It should be noted that ITO is preferable, with which high transparency, high conductivity, and the like can be achieved.

To form the hole transport layer 303, the light emission layer 304, and the electron transport layer 305, a conventionally known material for an organic EL element can be used without any change.

The upper electrode 306 is formed with, for example, films made of lithium fluoride (LiF) and aluminum (Al) in such a manner that the films have thicknesses of 5 nm to 20 nm, and 50 nm to 200 nm, respectively. The method for forming the films is, for example, the vacuum vapor deposition method.

Further, in a case where an organic EL element of a bottom emission type is to be produced, the upper electrode 306 in the upper part of the organic EL element 1 may be an electrode of a light reflection type. With this, light that is generated in the organic EL element 1 and travels upward on a side opposite to the display side is reflected by the upper electrode 306. As a result, the reflected light is also used for display, which improves the utilization efficiency of light emitted by the organic EL element.

### [Method for Producing Display Element, Optical Element, or Illumination Element]

The present disclosure, in another aspect, relates to a method for producing a display element, an optical element, or an illumination element. The producing method according to the present disclosure, in one or a plurality of embodiments, is a method for producing a display element, an optical element, or an illumination element according to the present disclosure. Further, the producing method according to the present disclosure, in one or a plurality of embodiments, is a producing method including the steps of: applying the polyamide resin solution according to the present disclosure to a base; forming a polyamide film after the applying step; and forming a display element, an optical element, or an illumination element on a surface of the polyamide film that is not in contact with the base. The producing method according to the present disclosure may further include the step of separating the display element, the optical element, or the illumination element formed on the base, from the base.

### <One Non-Limited Embodiment of Method for Producing Organic EL Element>

The following description describes one embodiment of a method for producing an organic EL element, as one embodiment of the method for producing the display element according to the present disclosure, while referring to the drawings.

A method for producing the organic EL element 1 illustrated in FIG. 4 includes a fixing step, a gas barrier layer forming step, a thin film transistor forming step, an organic EL layer forming step, a sealing step, and a separating step. Hereinafter, each step is described in detail.

### 1. Fixing Step

In the fixing step, the transparent resin substrate 100 is fixed on the base 500. The method for fixing is not limited particularly, and examples of the same include a method of applying an adhesive between the base 500 and the transparent substrate, and a method of fusing a part of the transparent resin substrate 100 onto the base 500. As the material for the base, for example, glass, a metal, silicon, a resin, or the like can be used. These may be used alone, or two or more of the materials may be used in combination appropriately. Further alternatively, the fixing may be achieved by applying a mold release agent or the like on the base 500, and attaching the transparent resin substrate 100 on the same. In one or a plurality of embodiments, a polyamide resin composition according to the present disclosure is applied on the base 500, and is dried, whereby the polyamide film 100 is formed.

### 2. Gas Barrier Layer Forming Step

In the gas barrier layer forming step, the gas barrier layer 101 is formed on the transparent resin substrate 100. The forming method is not limited particularly, and any known method can be used.

### 3. Thin Film Transistor Forming Step

In the thin film transistor forming step, the thin film transistor B is formed on the gas barrier layer. The forming method is not limited particularly, and any known method can be used.

### 4. Organic EL Layer Forming Step

The organic EL layer forming step includes a first step and a second step. In the first step, the flattening layer 301 is formed. The method for producing the flattening layer 301 is, for example, a method of applying a photosensitive transparent resin by the spin coating method, the slit coating method, the ink-jet method, or the like. Here, it is necessary to provide an opening in the flattening layer 301, so that the connection part 300 can be formed in the second step. The flatten layer has a film thickness of about 100 nm to 2 μm, typically, but the thickness is not limited to this.

In the second step, first of all, the connection part 300 and the lower electrode 302 are formed simultaneously. Examples of the method for forming these include the sputtering method, the vacuum vapor deposition method, and the ion plating method. Each of these electrodes has a film thickness of about 50 nm to 200 nm, typically, but the thickness is not limited to this. Thereafter, the hole transport layer 303, the light emission layer 304, the electron transport layer 305, and the upper electrode 306, which is a cathode of the organic EL element 1, are formed. As a method for forming these, a method suitable for the used materials and the laminate configuration can be used, such as the vacuum vapor deposition method or the application method. Further, the configuration of the organic layers of the organic EL element 1 may additionally include other known organic layers selected appropriately, such as a positive hole injection layer, an electron transport layer, a positive hole blocking layer, and an electron blocking layer, irrespective of the description of the present example.

### 5. Sealing Step

In the sealing step, the organic EL layer C is sealed from above the upper electrode 306, by the sealing member 400. The sealing member 400 can be made of glass, a resin, ceramic, a metal, a metal compound, or a composite of any of these, for example, and an optimal material can be appropriately selected.

### 6. Separating Step

In the separating step, the formed organic EL element 1 is separated from the base 500. A method for realizing the separating step is, for example, a method of separating the same from the base 500 physically. Here, the configuration may be such that a separation layer is provided on the base 500, or the separation may be achieved by inserting a wire between the base 500 and the display element. Further, other examples of the separating method include the following methods: a method in which a separation layer is not provided on an end of the base 500, and the element is taken out by cutting the inside from the end after the element is formed; a method in which a layer composed of a silicon layer and the like is provided between the base 500 and the element, and the element is separated by laser irradiation; a method in which heat is applied to the base 500 so as to separate the base 500 and the transparent substrate; and a method in which the base 500 is removed with a solvent. Each of these methods may be used alone, or a plurality of arbitrary methods among these may be used in combination. In one or more embodiments, it is possible to control the adhesion between the polyamide film and the base with a silane coupling agent, which makes it also possible to physically separate the organic EL element 1 without use of the above-described complicated steps.

### [Display Device, Optical Device, Illumination Device]

The present disclosure, in one aspect, relates to a display device, an optical device, or an illumination device in which the display element, optical element, or illumination element according to the present disclosure is used, and further relates to a method for manufacturing the same. Though not limited to these, examples of the display device include an image pickup element, examples of the optical device include an optical and electrical combined circuit, and examples of the illumination device include a TFT-LCD, an OEL illumination, etc.

### [Sensor Element Manufacturing Method]

The present disclosure, in another aspect, relates to a method for manufacturing a sensor element, the method including the following steps (A) and (B):

(A) applying the polyamide solution according to the present disclosure on a base, so as to form a polyamide film on the base; and

(B) forming a sensor element on a surface of the polyamide film.

As the base, the above-described base body can be used.

In the step (A) in the manufacturing method of the present aspect, a laminated composite material can be formed. The step (A) in the manufacturing method of the present aspect, in one or more embodiments, includes the steps (i) and (ii).

(i) applying the above-described polyamide solution on the base (see Step A in FIG. 1); and

(ii) heating the applied polyamide solution after the step (i), so as to form a polyamide film (see Step B in FIG. 1).

The application in the step (i), and the heating temperature in the step (ii), can be set similarly to the case described above. The manufacturing method in the present aspect may include a curing treatment step (iii) of hardening the polyamide film, after the step (ii). The temperature and time of the curing treatment can be set similarly to the case described above.

The formation of a sensor element in the step (B) of the manufacturing method of the present aspect is not limited particularly, an element that is conventionally manufactured or is to be manufactured can be appropriately formed in accordance with the manufactured sensor element.

The manufacturing method of the present aspect, in one or more embodiments, includes a step of separating the formed sensor element from the glass plate, as a step (C) after the step (B). In the separating step (C), the produced sensor element is separated from the base. As a method for implementing the separating step, the method similar to that described above can be used.

### [Sensor Element]

The present disclosure, in one or more embodiments, relates to a sensor element manufactured by the manufacturing method of the present aspect. Examples of the “sensor element” manufactured by the manufacturing method according to the present disclosure, in one or more non-limited embodiments, include a sensor element having a polyamide film formed with the polyamide solution used in the manufacturing method of the present disclosure. Further, in one or more other embodiments, the “sensor element” manufactured by the manufacturing method according to the present disclosure is a sensor element formed on the polyamide film formed on the base, and further, in one or more other embodiments, a sensor element separated from the base as required. Examples of the sensor element, in one or more embodiments, include a sensor element that is capable of receiving electromagnetic wave, a sensor element that is capable of detecting a magnetic field, a sensor element that is capable of detecting a change in electrostatic capacitance, and an element that is capable of detecting a change in pressure. Examples of such a sensor element, in one or more embodiments, include an image pickup element, a radiation sensor element, a photo-sensor element, a magnetic sensor element, an electrostatic capacitance sensor element, a touch sensor element, and a pressure sensor element. Examples of the radiation sensor element, in one or more embodiments, include an X-ray sensor element. The sensor element of the present disclosure, in one or more embodiments, encompasses those manufactured by using the polyamide solution according to the present disclosure, and/or those manufactured by using the laminated composite material according to the present disclosure, and/or those manufactured by the element manufacturing method according to the present disclosure. Further, the forming of a sensor element in the present disclosure, in one or more embodiments, encompasses the forming of a photoelectric conversion element and a driving element for the same.

### [Input Device]

The “sensor element” manufactured by the manufacturing method according to the present disclosure, in one or more non-limited embodiments, can be used as an input device, and examples of the input device, in one or more embodiments, include optical, image pickup, magnetic, electrostatic capacitance, and pressure input devices. Examples of such an input device, in one or more non-limited embodiments, include a radiation image pickup device, a visible light image pickup device, a magnetic sensor device, a touch panel, a finger print authentication panel, and a light emission body in which a piezoelectric element is used. Examples of the radiation image pickup device, in one or more embodiments, include an X-ray image pickup device. Further, the input device of the present disclosure, in one or more non-limited embodiments, may have a function as an output device such as a display function.

### <One Non-Limited Embodiment of Sensor Element>

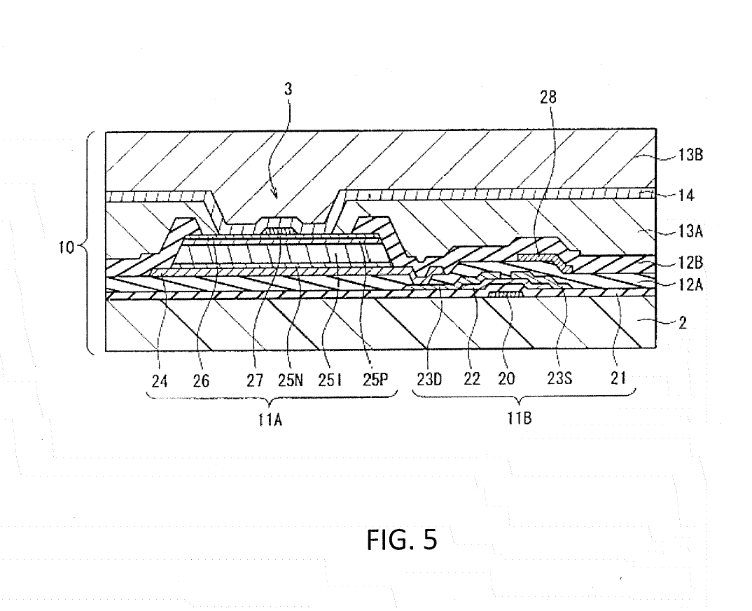

Hereinafter, one embodiment of a sensor element that can be manufactured by the manufacturing method of the present aspect is described with reference to FIG. 5.

FIG. 5 is a schematic cross-sectional view illustrating a sensor element 10 according to one embodiment. The sensor element 10 includes a plurality of pixels. This sensor element 10 includes pixel circuits formed on a surface of a substrate 2, the pixel circuits including a plurality of photodiodes 11A (photoelectric conversion elements), and thin film transistors (TFT) 11B as driving elements for these photodiodes 11A. This substrate 2 is the polyamide film formed on a base (not shown) by the step (A) of the manufacturing method of the present aspect. By the step (B) of the manufacturing method of the present aspect, the photodiodes 11A (photoelectric conversion elements) and the thin film transistors 11B as driving elements for these photodiodes 11A are formed.

A gate insulation film 21 is provided on the substrate 2, and is formed with, for example, a single layer film composed of one of a silicon oxide (SiO₂) film, a silicon oxynitride (SiON) film, and a silicon nitride film (SiN), or a laminate film composed of two or more types of these films. A first interlayer insulation film 12A is provided on the gate insulation film 21, and is formed with an insulation film such as a silicon oxide film or a silicon nitride film. This first interlayer insulation film 12A, as well be described below, also functions as a protection film (passivation film) covering the thin film transistor 11B.

### (Photodiode 11A)

A photodiode 11A is provided on a selective area on the substrate 2, with the gate insulation film 21 and the first interlayer insulation film 12A being interposed between the photodiode 11A and the substrate 2. More specifically, the photodiode 11A is formed by laminating a lower electrode 24, an n-type semiconductor layer 25N, an i-type semiconductor layer 251, a p-type semiconductor layer 25P, and an upper electrode 26 on the first interlayer insulation film 12A in the stated order. The upper electrode 26 is, for example, an electrode for supplying a reference potential (bias potential) upon photoelectric conversion to the above-described photoelectric conversion layer, and is connected to a wiring layer 27, which is a power source wiring for reference potential supply. This upper electrode 26 is formed with, for example, a transparent conductive film made of indium tin oxide (ITO) or the like.

### (Thin Film Transistor 11B)

The thin film transistor 11B is formed with, for example, a field effect transistor (FET). In the thin film transistor 11B, for example, a gate electrode 20 made of titanium (Ti), Al, Mo, tungsten (W), chromium (Cr), or the like is formed on the substrate 2, and the above-described gate insulation film 21 is formed on the gate electrode 20. Further, a semiconductor layer 22 is formed on the gate insulation film 21, and this semiconductor layer 22 has a channel area. On the semiconductor layer 22, a source electrode 23S and a drain electrode 23D are formed. More specifically, here, the drain electrode 23D is connected to a lower electrode 24 in the photodiode 11A, and the source electrode 23S is connected to a relay electrode 28.

In the sensor element 10, in a layer above the photodiode 11A and the thin film transistor 11B, a second interlayer insulation film 12B, a first flattening film 13A, a protection film 14, and a second flattening film 13B are provided in the stated order. In the first flattening film 13A, an opening 3 is formed so as to correspond to the vicinities of the area where the photodiode 11A is formed.

By forming, for example, a wavelength conversion member on the sensor element 10, a radiation image pickup device can be produced.

The present disclosure can relate to one or more embodiments described below:

<1>. A polyamide solution comprising an aromatic polyamide and a solvent,

wherein a Young's modulus of at least one direction of a cast film produced by casting the polyamide solution on a glass plate is 3.0 GPa or more, and a tensile strength of the cast film is 100 MPa or more and 250 MPa or less.

<2> The polyamide solution according to <1>, wherein the Young's modulus is 5.0 GPa or more.
<3> The polyamide solution according to <1> or <2>, wherein the tensile strength is 180 MPa or more and 250 MPa or less.
<4> The above-described polyamide solution wherein a diacid dichloride monomer represented by a following general formula (III) makes up in total 90 mol % or less of the whole diacid dichloride monomer used for the synthesis of the aromatic polyamide:

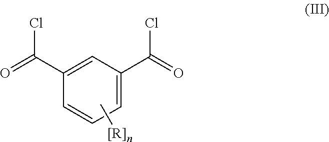

where n=4, and R is independently selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, and a substituted alkyl ester group as well as combinations of the same.

<5> The polyamide solution according to <4>, wherein the diacid dichloride monomer represented by the general formula (III) makes up in total 15 mol % or more and 45 mol % or less of the whole diacid dichloride monomer used for the synthesis.
<6> The polyamide solution according to any one of <1> to <5>, wherein at least one of the constitutional units of the aromatic polyamide has a free carboxyl group.
<7> A polyamide solution comprising an aromatic polyamide and a solvent,

wherein a Young's modulus of at least one direction of a cast film produced by casting the polyamide solution on a glass plate is 3.0 GPa or more, and

a polyamide of the polyamide solution has a constitutional unit represented by following general formulae (I) and (II):

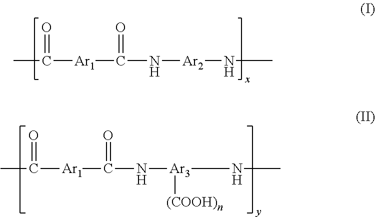

where x represents mol % of the constitutional unit of the formula (I), y represents mol % of the constitutional unit of the formula (II), x is 70 to 100 mol %, y is 0 to 30 mol %, and n is 1 to 4,

Ar₁ is selected from the group comprising:

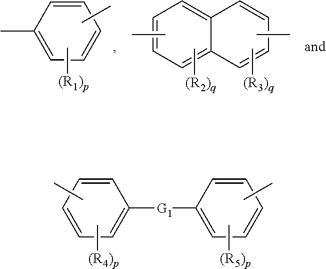

where p=4, and q=3,
R₁, R₂, R₃, R₄ and R₅ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₁ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group;
and an OZO group where Z is an aryl group or a substituted aryl group,

Ar₂ is selected from the group comprising:

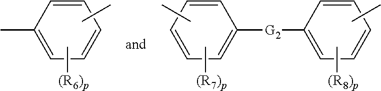

where p=4,
R₆, R₇ and R₈ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₂ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group, and

Ar₃ is selected from the group comprising:

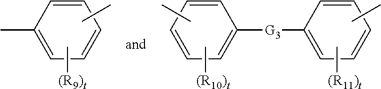

where t=0 to 3,
R₉, R₁₀ and R₁₁ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₃ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group.
   <8> The polyamide solution according to <7>, wherein the Young's modulus is 5.0 GPa or more.
   <9> The polyamide solution according to <7> or <8>, wherein the tensile strength is 100 MPa or more and 250 MPa or less.
   <10> The polyamide solution according to <9>, wherein the tensile strength is 180 MPa or more and 250 MPa or less.
   <11> The polyamide solution according to any one of <7> to <10>, wherein the diacid dichloride monomer represented by a following general formula (III) makes up in total 90 mol % or less of the whole diacid dichloride monomer used for the synthesis of the aromatic polyamide:

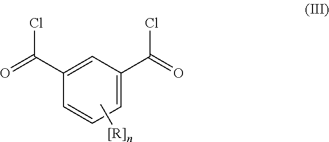

where n=4, and R is independently selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, and substituted alkyl ester group as well as combinations of the same.

<12> The polyamide solution according to <11>, wherein the diacid dichloride monomer represented by the general formula (III) makes up in total 15 mol % or more and 45 mol % or less of the whole diacid dichloride monomer used for the synthesis.
<13> The polyamide solution according to any one of <7> to <12>, wherein at least one of the constitutional units of the aromatic polyamide has a free carboxyl group.
<14> The polyamide solution according to any one of <1> to <13> for use in a method for manufacturing a display element, an optical element, an illumination element or a sensor element, the method comprising the steps of:

a) casting the polyamide solution onto a base;

b) causing a polyamide film to be formed from the applied polyamide solution on the base after the casting step (a); and

c) forming the display element, the optical element, the illumination element or the sensor element on a surface of the polyamide film.

<15.> The polyamide solution according to any one of <1> to <14>, further containing a multifunctional epoxide.
<16> The polyamide solution according to <15>, wherein the multifunctional epoxide is an epoxide having two or more glycidyl groups, or an epoxide having two or more alicyclic structures.
<17> The polyamide solution according to <15> or <16>, wherein the multifunctional epoxide is selected from the group consisting of the multifunctional epoxides expressed by following general formulae (I) to (IV):

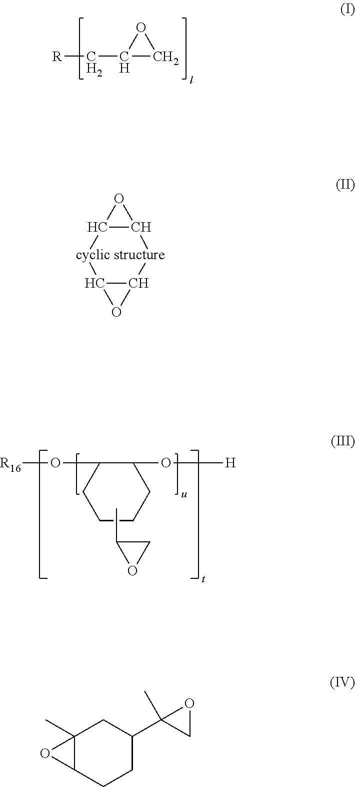

where, in the formula (I), I represents the number of glycidyl groups, and R is selected from the group consisting of:

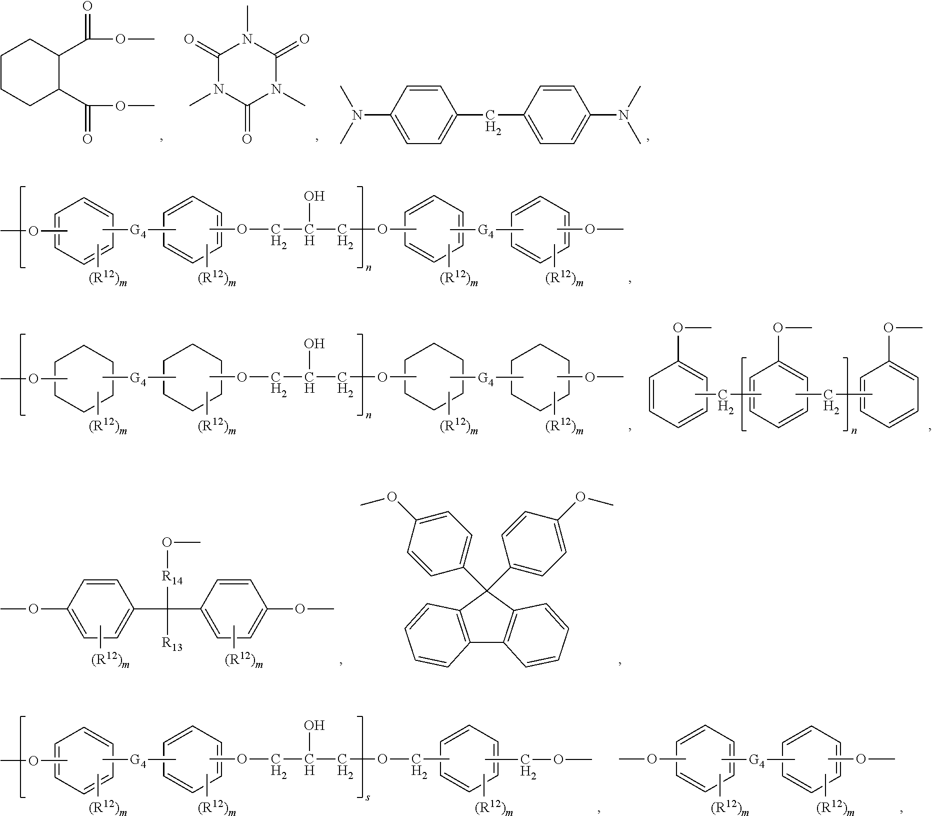

and a combination thereof,
where m is 1 to 4,
n and s represent the average unit numbers, each of which is in the range of 0 to 30 independently,
R₁₂ is selected from the group consisting of hydrogen, halogen (fluoride, chloride, bromide, and iodide), an alkyl group, a substituted alkyl group such as a halogenated alkyl group, a nitro group, a cyano group, a thioalkyl group, an alkoxy group, a substituted alkoxy group such as a halogenated alkoxy group, an aryl group, or a substituted aryl group such as a halogenated aryl group, an alkyl ester group and a substituted alkyl ester group such as a halogenated alkyl ester group, and combinations thereof,
G₄ is selected from the group consisting of a covalent bond; a CH₂ group; a C(CH₃)₂ group; a C(CF₃)₂ group; a C(CX₃)₂ group where X is a halogen; a CO group; an O atom; a S atom; a SO₂ group; a Si (CH₃)₂ group; a 9,9-fluorene group; a substituted 9,9-fluorene; and an OZO group where Z is an aryl group or a substituted aryl group, such as a phenyl group, a biphenyl group, a perfluorobiphenyl group, a 9,9-bisphenylfluorene group, or a substituted 9,9-bisphenylfluorene,
R₁₃ is either hydrogen or a methyl group, and
R₁₄ is a divalent organic group,

in the formula (II), the cyclic structure is selected from the group consisting of:

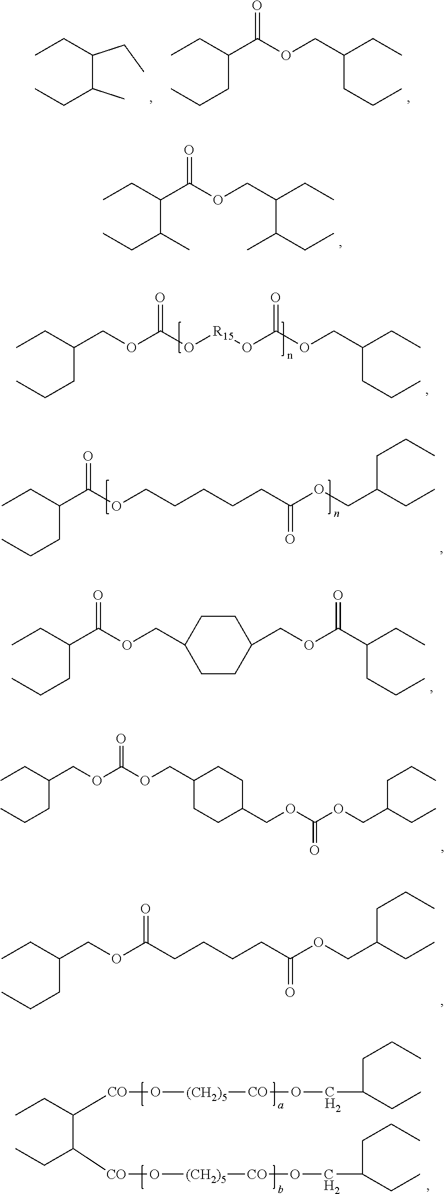

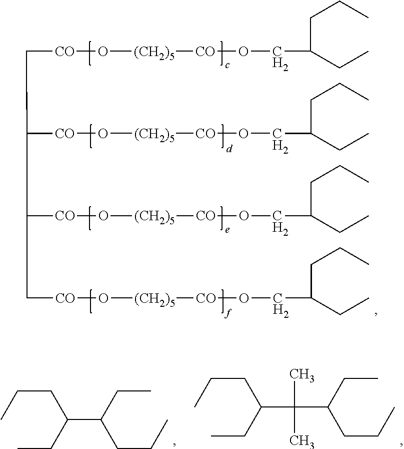

and a combination thereof,
where R₁₅ is a C2-C18 alkyl chain, which may be a linear chain, a branched chain, or a chain including a cycloalkane structure,
m and n represent the average unit numbers, each of which is in the range of 1 to 30 independently, and
each of a, b, c, d, e and f represents the number in the range of 0 to 30 independently, and

in the formula (III), R₁₆ is a C2-C18 alkyl chain, which may be a linear chain, a branched chain, or a chain including cycloalkane, and t and u are the average unit numbers, each of which is in the range of 0 to 30 independently.

<18> A polyamide film obtained by casting the polyamide solution according to any one of <1> to <17> onto a base.
<19> A laminated composite material, comprising a glass plate and a polyamide resin layer;

wherein the polyamide resin layer is laminated on one surface of the glass plate, and

the polyamide resin is a polyamide resin produced by casting the polyamide solution according to any one of <1> to <17> on a glass plate.

<20> A method for manufacturing a display element, an optical element, an illumination element or a sensor element, comprising the steps of:

a) casting the polyamide solution according to any one of <1> to <17> onto a base;

b) causing a polyamide film to be formed from the applied polyamide solution on the base after the applying step (a); and

c) forming the display element, the optical element, the illumination element or the sensor element, on a surface of the polyamide film.

<21> A display element, an optical element, an illumination element, or a sensor element manufactured by the manufacturing method according to <20>.

### Examples

Aromatic polyamide solutions (Examples 1 to 6) were prepared by using components shown in Table 1 and the following description. Young's moduli and tensile strengths of films formed by using the prepared polyamide solutions were measured as follows.

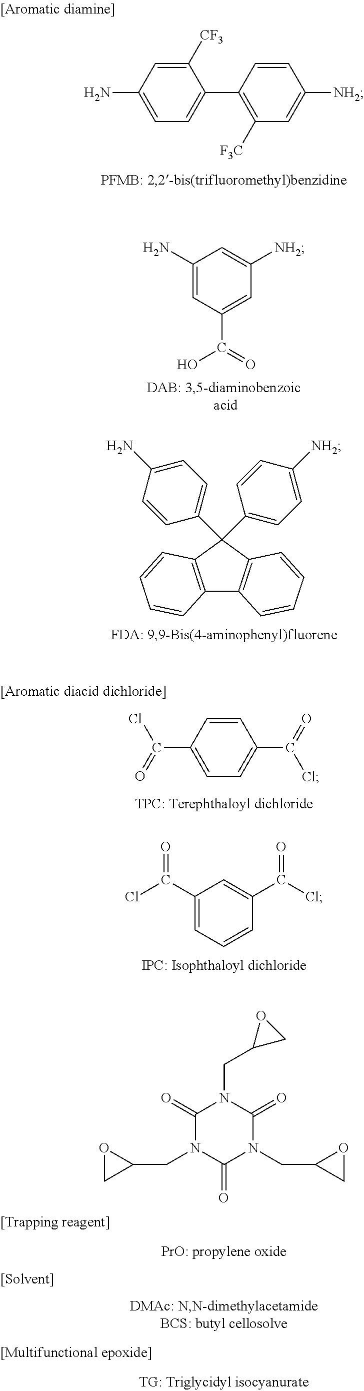 [SMILES: Nc1ccc(-c2ccc(N)cc2C(F)(F)F)c(C(F)(F)F)c1 ; Nc1cc(N)cc(C(=O)O)c1 ; Nc1ccc(C2(c3ccc(N)cc3)c3ccccc3-c3ccccc32)cc1 ; O=C(Cl)c1ccc(C(=O)Cl)cc1 ; O=C(Cl)c1cccc(C(=O)Cl)c1 ; O=c1n(CC2CO2)c(=O)n(CC2CO2)c(=O)n1CC1CO1]

### [Preparation of Polyamide Solution]

Hereinafter, a common method for preparing a polyamide solution of Example 1 is described. The polyamide solution of Example 1 contained, in DMAc, 5% by weight of a copolymer of TPC, IPC, PFMB, and DAB (molar ratio: TPC/IPC/PFMB/DAB=10%/90%/95%15%).

Into a 250 ml three mouth round bottom flask equipped with a mechanical agitator, a nitrogen inlet port, and an outlet port, PFMB (3.241 g, 0.0095 mol), DAB (0.0761 g, 0.0005 mol), and DMAc (75 ml) were charged. After PFMB and DAB were dissolved completely, PrO (1.7 g, 0.03 mol) was added to the solution. The solution was cooled to 0° C. After the addition, TPC (0.203 g, 0.001 mol) and IPC (1.827 g, 0.009 mol) were added under agitation. Interior walls of the flask were washed with DMAc (1.5 ml). Two hours later, benzoyl chloride (0.032 g, 0.23 mmol) was added to the solution, and the solution was agitated for two hours additionally, whereby a solution 2 was obtained.

The polyamide solutions of Examples 2 to 5 were prepared in a similar manner to that in Example 1, as 5% by weight polyamide solutions.

The solution of Example 6 was prepared by adding triglycidyl isocyanurate (TG) of 5% by weight with respect to polyamide, to the polyamide solution of Example 4, and further agitating for two hours.

### [Formation of Polyamide Film]

The polyamide solutions thus prepared of Examples 1 to 6 were casted on glass substrates so that films were formed, and properties of the same were examined.

The polyamide solutions were applied on flat glass substrates (10 cm×10 cm, trade name: EAGLE XG, manufactured by Corning Inc., U.S.A.) by spin coating. Drying at 60° C. for 30 minutes or more was performed, and thereafter, the temperature was raised from 60° C. to 220° C., 330° C., or 350° C. by heating, and the temperature of 220° C., 330° C., or 350° C. was kept in vacuum or in an inactive atmosphere for 30 minutes or for 60 minutes so as to cure films, whereby polyamide films 1 to 97 were obtained (thickness: about 10 μm).

### [Measurement of Young's Modulus of at Least One Direction of Cast Film]

Tensile tests were carried out using a universal tensile testing machine (Autograph AG-5kNX, manufactured by Shimadzu Corporation), and Young's moduli of at least one direction of the cast films were calculated from the measurement results.

The measurement conditions were as follows:

Sample size: dumbbell-like test piece (in accordance with JIS K 6251 (Dumbbell No. 1))

Parallel part width: 10 mm

Length: 40 mm (initial distance between mark lines)

Gripper distance: 90 mm

Tensile speed: 10 mm/min

[Tensile strength of cast film]

Tensile tests were carried out using a universal tensile testing machine (Autograph AG-5kNX, manufactured by Shimadzu Corporation), and tensile strengths of the cast films were calculated from the measurement results.

The measurement conditions were the same as those described above.

TABLE 1

| | Composition | | | | | | | Film | |
|---|---|---|---|---|---|---|---|---|---|
| | Diamine | | | | Dichloride | | Epoxide | | Tensile |
| | PFMB | DAB | FDA | 4.4′-ODA | IPC | TPC | TG | Modulus | Strength |
| | mol % | mol % | mol % | mol % | mol % | mol % | wt % | GPa | MPa |
| Ex. 1 | 95 | 5 | 0 | 0 | 90 | 10 | 0 | 3.1 | 129 |
| Ex. 2 | 95 | 5 | 0 | 0 | 80 | 20 | 0 | 3.2 | 144 |
| Ex. 3 | 95 | 5 | 0 | 0 | 70 | 30 | 0 | 3.9 | 169 |
| Ex. 4 | 95 | 5 | 0 | 0 | 30 | 70 | 0 | 5.8 | 189 |
| Ex. 5 | 80 | 5 | 15 | 0 | 0 | 100 | 0 | 5.8 | 209 |
| Ex. 6 | 95 | 5 | 0 | 0 | 30 | 70 | 5 | 4.0 | 220 |

As shown in Table 1, the polyamide solutions of Examples 1 to 6 exhibited Young's moduli of 3.0 GPa or more and tensile strengths of 100 MPa or more.

The embodiments have been described, hereinabove. It will be apparent to those skilled in the art that the above methods and apparatuses may incorporate changes and modifications without departing from the general scope of this disclosure. It is intended to include all such modifications and alterations insofar as they come within the scope of the appended claims or the equivalents thereof. Although the description above contains much specificity, this should not be construed as limiting the scope of the disclosure, but as merely providing illustrations of some of the embodiments of this disclosure. Various other embodiments and ramifications are possible within its scope.

Furthermore, notwithstanding that the numerical ranges and parameters setting forth the broad scope of the disclosure are approximations, the numerical values set forth in the specific examples are reported as precisely as possible. Any numerical value, however, inherently contain certain errors necessarily resulting from the standard deviation found in their respective testing measurements.

What is claimed is:

1. A polyamide solution comprising an aromatic polyamide and a solvent,
wherein a Young's modulus of at least one direction of a cast film produced by casting the polyamide solution on a glass plate is 3.0 GPa or more, and a tensile strength of the cast film is 100 MPa or more and 250 MPa or less.

2. The polyamide solution according to claim 1, wherein the Young's modulus is 5.0 GPa or more.

3. The polyamide solution according to claim 1, wherein the tensile strength is 180 MPa or more and 250 MPa or less.

4. The polyamide solution according to claim 1,
wherein a diacid dichloride monomer represented by a following general formula (III) makes up in total 90 mol % or less of the whole diamine monomer used for the synthesis of the polyamide: 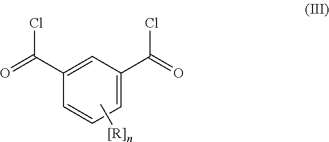
where n=4, and R is independently selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, and a substituted alkyl ester group as well as combinations of the same.

5. The polyamide solution according to claim 4, wherein the as well as combinations of the same represented by the general formula (III) makes up in total 15 mol % or more and 45 mol % or less of the whole as well as combinations of the same used for the synthesis.

6. The polyamide solution according to claim 1, wherein at least one of the constitutional units of the aromatic polyamide has a free carboxyl group.

7. A polyamide solution comprising an aromatic polyamide and a solvent,
wherein a Young's modulus of at least one direction of a cast film produced by casting the polyamide solution on a glass plate is 3.0 GPa or more, and
an aromatic polyamide of the polyamide solution has a constitutional unit represented by following general formulae (I) and (II): 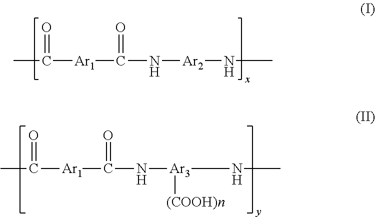
where x represents mol % of the constitutional unit of the formula (I), y represents mol % of the constitutional unit of the formula (II), x is 70 to 100 mol %, y is 0 to 30 mol %, and n is 1 to 4,
Ar₁ is selected from the group comprising: 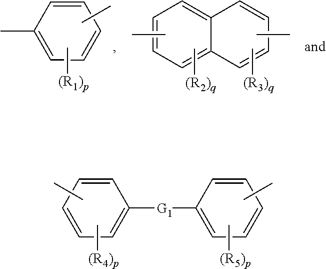
where p=4, and q=3,
R₁, R₂, R₃, R₄ and R₅ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₁ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group,
Ar₂ is selected from the group comprising: 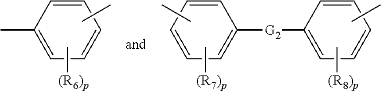
where p=4,
R₆, R₇ and R₈ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₂ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group, and
Ar₃ is selected from the group comprising: 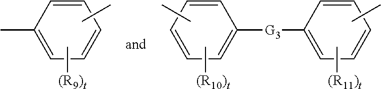
where t=0 to 3,
R₉, R₁₀ and R₁₁ are selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, a substituted alkyl ester group, and combinations thereof, and
G₃ is selected from the group comprising: a covalent bond; a CH₂ group; a C(CH₃)₂ group; a C(CF₃)₂ group; a C(CX₃)₂ group where X is halogen; a CO group; an O atom; an S atom; an SO₂ group; an Si (CH₃)₂ group; a 9,9-fluorene group; a substituted 9,9-fluorene group; and an OZO group where Z is an aryl group or a substituted aryl group.

8. The polyamide solution according to claim 7, wherein the Young's modulus is 5.0 GPa or more.

9. The polyamide solution according to claim 7, wherein the tensile strength is 100 MPa or more and 250 MPa or less.

10. The polyamide solution according to claim 9, wherein the tensile strength is 180 MPa or more and 250 MPa or less.

11. The polyamide solution according to claim 7,
wherein the diacid dichloride monomer represented by a following general formula (III) makes up in total less than 90 mol % of the whole diacid dichloride monomer used for the synthesis of the aromatic polyamide: 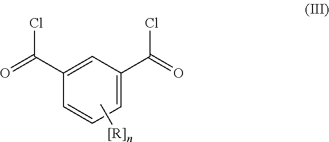
where n=4, and R is independently selected from the group comprising hydrogen, halogen, an alkyl group, a substituted alkyl group, a nitro group, a cyano group, a thioalkyl group, an alkoxy group, a substituted alkoxy group, an aryl group, a substituted aryl group, an alkyl ester group, and substituted alkyl ester group as well as combinations of the same.

12. The polyamide solution according to claim 11, wherein the diacid dichloride monomer represented by the general formula (III) makes up in total 15 mol % or more and 45 mol % or less of the whole diamine monomer used for the synthesis.

13. The polyamide solution according to claim 7, wherein at least one of the constitutional units of the aromatic polyamide has a free carboxyl group.

14. The polyamide solution according to claim 1 for use in a method for manufacturing a display element, an optical element, an illumination element or a sensor element, the method comprising the steps of:
a) casting the polyamide solution onto a base;
b) causing a polyamide film to be formed from the applied polyamide solution on the base after the casting step (a); and
c) forming the display element, the optical element, the illumination element or the sensor element on a surface of the polyamide film.

15. The polyamide solution according to claim 1, further containing a multifunctional epoxide.

16. The polyamide solution according to claim 15, wherein the multifunctional epoxide is an epoxide having two or more glycidyl groups, or an epoxide having two or more alicyclic structures.

17. The polyamide solution according to claim 15, wherein the multifunctional epoxide is selected from the group consisting of the multifunctional epoxides expressed by following general formulae (I) to (IV): 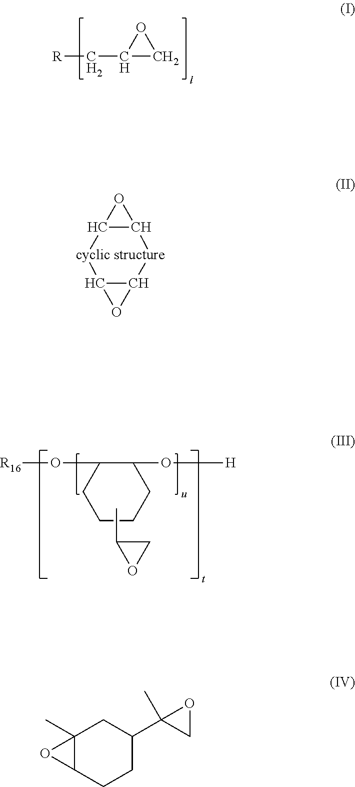
where, in the formula (I), I represents the number of glycidyl groups, and R is selected from the group consisting of: 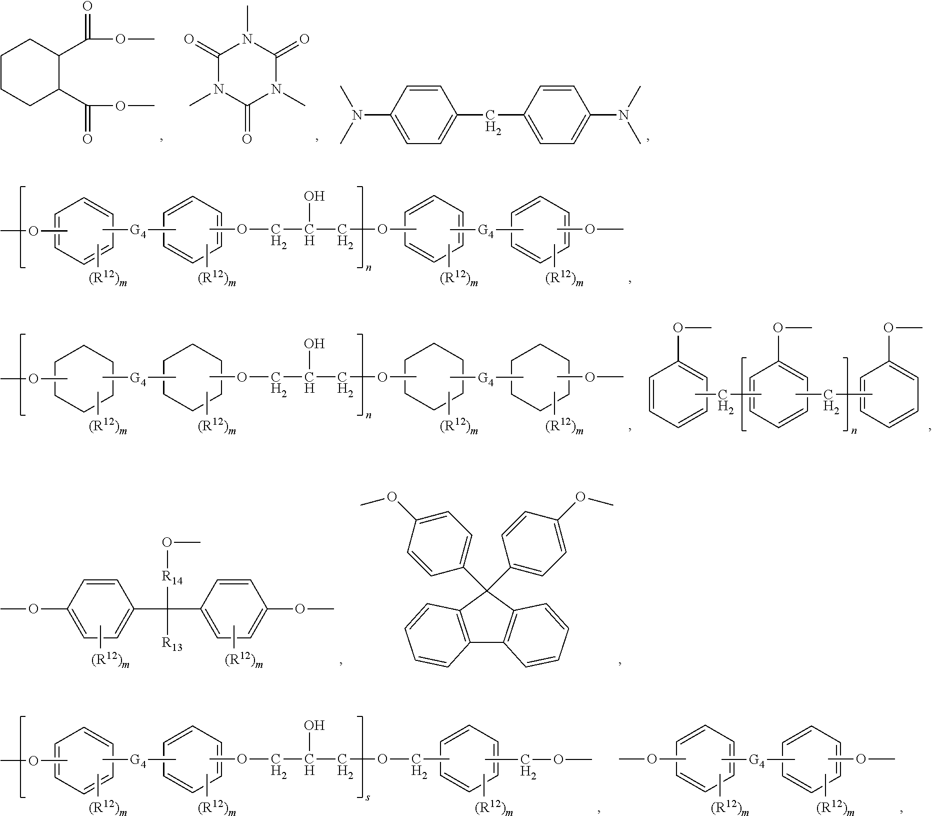
and a combination thereof,
where m is 1 to 4,
n and s represent the average unit numbers, each of which is in the range of 0 to 30 independently,
R₁₂ is selected from the group consisting of hydrogen, halogen (fluoride, chloride, bromide, and iodide), an alkyl group, a substituted alkyl group such as a halogenated alkyl group, a nitro group, a cyano group, a thioalkyl group, an alkoxy group, a substituted alkoxy group such as a halogenated alkoxy group, an aryl group, or a substituted aryl group such as a halogenated aryl group, an alkyl ester group and a substituted alkyl ester group such as a halogenated alkyl ester group, and combinations thereof,
G₄ is selected from the group consisting of a covalent bond; a CH₂ group; a C(CH₃)₂ group; a C(CF₃)₂ group; a C(CX₃)₂ group where X is a halogen; a CO group; an O atom; a S atom; a SO₂ group; a Si (CH₃)₂ group; a 9,9-fluorene group; a substituted 9,9-fluorene; and an OZO group where Z is an aryl group or a substituted aryl group, such as a phenyl group, a biphenyl group, a perfluorobiphenyl group, a 9,9-bisphenylfluorene group, or a substituted 9,9-bisphenylfluorene,
R₁₃ is either hydrogen or a methyl group, and
R₁₄ is a divalent organic group,
in the formula (II), the cyclic structure is selected from the group consisting of: 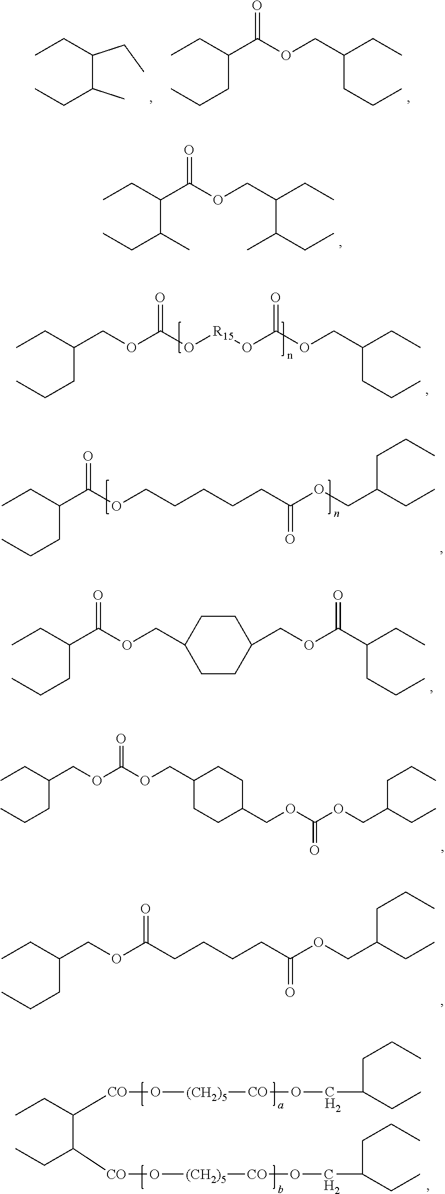 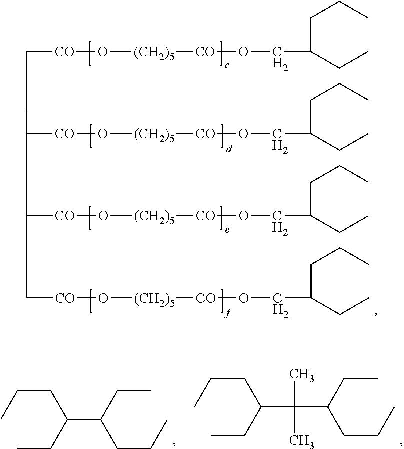
and a combination thereof,
where R₁₅ is a C2-C18 alkyl chain, which may be a linear chain, a branched chain, or a chain including a cycloalkane structure,
m and n represent the average unit numbers, each of which is in the range of 1 to 30 independently, and
each of a, b, c, d, e and f represents the number in the range of 0 to 30 independently, and
in the formula (III), R₁₆ is a C2-C18 alkyl chain, which may be a linear chain, a branched chain, or a chain including cycloalkane, and t and u are the average unit numbers, each of which is in the range of 0 to 30 independently.

18. A polyamide film obtained by casting the polyamide solution according to claim 1 onto a base.

19. A laminated composite material, comprising a glass plate and a polyamide resin layer,
wherein the polyamide resin layer is laminated on one surface of the glass plate, and
the polyamide resin is a polyamide resin produced by casting the polyamide solution according to claim 1 on a glass plate.

20. A method for manufacturing a display element, an optical element, an illumination element or a sensor element, comprising the steps of:
a) casting the polyamide solution according to claim 1 onto a base;
b) causing a polyamide film to be formed from the applied polyamide solution on the base after the applying step (a); and
c) forming the display element, the optical element, the illumination element or the sensor element, on a surface of the polyamide film.
